(19) United States
(12) Patent Application Publication
(10) Pub. No.: US 2024/0282864 A1
(43) Pub. Date: Aug. 22, 2024

(54) INTEGRATED CIRCUIT SEMICONDUCTOR DEVICE

(71) Applicant: SAMSUNG ELECTRONICS CO., LTD., SUWON-SI (KR)

(72) Inventors: Dongkyu Lee, Suwon-si (KR); Sungil Park, Suwon-si (KR); Jaehyun Park, Suwon-si (KR); Jinwook Yang, Suwon-si (KR); Jinchan Yun, Suwon-si (KR); Cheoljin Yun, Suwon-si (KR); Daewon Ha, Suwon-si (KR); Kyuman Hwang, Suwon-si (KR)

(21) Appl. No.: 18/432,351

(22) Filed: Feb. 5, 2024

(30) Foreign Application Priority Data
Feb. 17, 2023 (KR) 10-2023-0021594

(51) Int. Cl. H01L 29/786; H01L 21/8238; H01L 27/06; H01L 27/088; H01L 29/06; H01L 29/08; H01L 29/423; H01L 29/66; H01L 29/775

(52) U.S. Cl. CPC H01L 29/78696; H01L 21/823807; H01L 27/0688; H01L 27/088; H01L 29/0673; H01L 29/0847; H01L 29/42392; H01L 29/66439; H01L 29/66545; H01L 29/775

(57) ABSTRACT

An integrated circuit semiconductor device with three dimensional transistors includes two gate-all-around transistors or multi-bridge channel field effect transistors may be vertically stacked to reduce unit area. The two stacked transistors may be separated by an isolation insulating layer. The two stacked transistors may be positioned on two opposite sides of the isolation insulating layer, with the structure of the two stacked transistors positioned in an opposite manner. According to embodiments of the present disclosure, metal wiring layers may be connected to the two stacked transistors at their far ends, away from the isolation insulating layer. A method for manufacturing an integrated circuit semiconductor device according to the present disclosure is described. Accordingly, aspects described herein may result in reduced unit area and easy manufacture of metal wiring layer connected to the transistors.

### CROSS-REFERENCE TO RELATED APPLICATION

This application is based on and claims priority under 35 U.S.C. § 119 to Korean Patent Application No. 10-2023-0021594, filed on Feb. 17, 2023, in the Korean Intellectual Property Office, the disclosure of which is incorporated by reference herein in its entirety.

### BACKGROUND

The present disclosure relates to an integrated circuit semiconductor device, and more particularly, to an integrated circuit semiconductor device including a three-dimensional transistor.

Integrated circuits are fundamental components in modern electronics and are deployed to perform a wide range of functions related to processing, controlling, and manipulating electrical signals and data in electronic devices. Transistors are semiconductor devices in integrated circuits. Transistors act as electronic switches or amplifiers, controlling the flow of current within a circuit. Primary types of transistors used in integrated circuits are Bipolar Junction Transistor (BJT), Metal-Oxide-Semiconductor Field-Effect Transistor (MOSFET), and Three-Dimensional Transistors.

In some cases, integrated circuits are limited by size constraints. The size of the integrated circuits can depend on the space occupied by transistors. Accordingly, there is a need in the art for integrated circuit devices that efficiently incorporate transistors to reduce the unit area.

### SUMMARY

The present disclosure relates to integrated circuit devices that include transistors. One or more embodiments include a device in which three-dimensional transistors are stacked on each other in the vertical direction to reduce the unit area of the transistors.

According to one or more embodiments, an integrated circuit semiconductor device includes a first transistor comprising a first nano-sheet stack structure, a first gate structure, and a first source and drain, the first transistor having a first horizontal direction, a second horizontal direction perpendicular to the first horizontal direction, and a vertical direction perpendicular to the first horizontal direction and the second horizontal direction, and a second transistor comprising a second nano-sheet structure, a second gate structure, and a second source and drain, the second transistor being separated from the first transistor by a transistor isolation insulating layer in the vertical direction.

The first nano-sheet stack structure comprises a plurality of first nano-sheet stacks spaced apart from each other in the first horizontal direction, where each of the plurality of first nano-sheet stacks comprises a plurality of first nano-sheets stacked in a vertical direction. The first gate structure extends in the second horizontal direction and surrounds the first nano-sheet stack structure in the vertical direction. The first source and drain is disposed on both sides of at least one first nano-sheet stack structure in the first horizontal direction. The second nano-sheet stack structure comprises a plurality of second nano-sheet stacks spaced apart from each other in the first horizontal direction, where each of the plurality of second nano-sheet stacks comprises a plurality of second nano-sheets stacked in the vertical direction. The second gate structure extends in the second horizontal direction and surrounds the second nano-sheet stack structure in the vertical direction. The second source and drain is disposed on both sides of at least one second nano-sheet stack in the first horizontal direction.

According to one or more embodiments, an integrated circuit semiconductor device includes a first transistor comprising a first nano-sheet stack structure, a first gate structure, and a first source and drain, the first transistor having a first horizontal direction, a second horizontal direction perpendicular to the first horizontal direction, and a vertical direction perpendicular to the first horizontal direction and the second horizontal direction, and a second transistor comprising a second nano-sheet structure, a second gate structure, and a second source and drain, the second transistor being separated from the first transistor by a transistor isolation insulating layer in the vertical direction.

The first nano-sheet stack structure comprises a plurality of first nano-sheet stacks spaced apart from each other in the first horizontal direction, where each of the plurality of first nano-sheet stacks comprises a plurality of first nano-sheets stacked in the vertical direction. The first gate structure extends in the second horizontal direction and surrounds the first nano-sheet stack in the vertical direction. The first source and drain is disposed on both sides of the first nano-sheet stack structure in the first horizontal direction. The second nano-sheet stack structure comprises a plurality of second nano-sheet stacks spaced apart from each other in the first horizontal direction, where each of the plurality of first nano-sheet stacks comprises a plurality of first nano-sheets stacked in the vertical direction The second gate structure extends in the second horizontal direction and surrounds the second nano-sheet stack structure in the vertical direction. The second source and drain is disposed on both sides of at least one second nano-sheet stack structure. The transistor isolation insulating layer includes a gate isolation insulating layer separating the first gate structure and the second gate structure in the vertical direction, and a source and drain isolation insulating layer separating the first source and drain and the second source and drain in the vertical direction. The height of the second source and drain is greater than or equal to the height of the first source and drain.

According to one or more embodiments, an integrated circuit semiconductor device includes a transistor isolation insulating layer having a first horizontal direction, a second horizontal direction perpendicular to the first horizontal direction, and a vertical direction perpendicular to the first horizontal direction and the second horizontal direction, a first transistor arranged under the transistor isolation insulating layer in an inverse vertical direction, the first transistor comprising a first nano-sheet stack structure, a first gate structure, a first source and drain, and a first metal wiring layer, and a second transistor arranged on the transistor isolation insulating layer in the vertical direction, the second transistor comprising a second nano-sheet structure, a second gate structure, a second source and drain, and a second metal wiring layer.

The first nano-sheet stack structure comprises a plurality of first nano-sheet stacks spaced apart from each other in the first horizontal direction, where each of the plurality of first nano-sheet stacks comprises a plurality of first nano-sheets stacked in the inverse vertical direction. The first gate structure extends in the second horizontal direction and surrounds the first nano-sheet stack structure in the vertical direction. The first source and drain is disposed on both sides of at least one first nano-sheet stack in the first horizontal direction. The first metal wiring layer is connected to the first source and drain in the inverse vertical direction.

The second nano-sheet stack structure comprises a plurality of second nano-sheet stacks spaced apart from each other in the first horizontal direction, where each of the plurality of second nano-sheet stacks comprises a plurality of second nano-sheets stacked in the vertical direction. The second gate structure extends in the second horizontal direction and surrounds the second nano-sheet stack structure in the vertical direction. The second source and drain is disposed on both sides of at least one second nano-sheet stack in the first horizontal direction. The second metal wiring layer is connected to the second source and drain in the vertical direction.

### BRIEF DESCRIPTION OF THE DRAWINGS

Embodiments of the disclosure will be more clearly understood from the following drawings:

FIG. 1 is a layout diagram of an integrated circuit semiconductor device according to an example embodiment;

FIGS. 2A and 2B are cross-sectional views of an integrated circuit semiconductor device according to an example embodiment;

FIGS. 3A and 3B are cross-sectional views of an integrated circuit semiconductor device according to an example embodiment;

FIGS. 4A and 4B are cross-sectional views of an integrated circuit semiconductor device according to an example embodiment;

FIGS. 5A and 5B are cross-sectional views illustrating an impurity concentration level of a first source and drain of the integrated circuit semiconductor device of FIG. 4A;

FIGS. 6A through 16B are cross-sectional views for describing a method of manufacturing the integrated circuit semiconductor device of FIGS. 1, 2A, and 2B;

FIGS. 17A through 25B are cross-sectional views for describing a method of manufacturing the integrated circuit semiconductor device of FIGS. 3A and 3B;

FIGS. 26A through 26C are cross-sectional views for describing an integrated circuit semiconductor device according to an example embodiment;

FIGS. 27A through 27C are cross-sectional views for describing an integrated circuit semiconductor device according to an example embodiment; and

FIGS. 28A and 28B are views for describing an integrated circuit semiconductor device according to an example embodiment.

### DETAILED DESCRIPTION

The present disclosure relates to integrated circuits. Integrated circuits integrate multiple electronic components onto a single semiconductor chip, enabling the development of small, powerful and energy-efficient devices. For example, integrated circuits may combine transistors, resistors, capacitors, and other components on a tiny silicon substrate, reducing the physical size of complex circuits while enhancing circuits' performance.

To meet the demand for more compact and powerful electronic devices, three-dimensional transistors are deployed in integrated circuits. For example, some integrated circuits use three-dimensional transistors to avoid short channel effects resulting from the increase of the degree of integration of integrated circuits, and to obtain high packing densities, fast switching speed and improved performance.

Three-dimensional transistors are transistors stacked vertically, allowing for multiple layers of transistors within a single chip. Examples of three-dimensional transistors includes fin-structured transistors, gate-all-around field-effect transistors, and 3D integration of planar transistor layers. The technology of three-dimensional transistors can enhance transistor density, resulting in faster processing speeds and a lower power consumption. Therefore, integrated circuits with three-dimensional transistors are ideal for power-hungry applications such as high-performance computing, artificial intelligence, and advanced data processing.

Three dimensional transistors in an integrated circuit semiconductor device may employ various technologies to improve efficiency. In some examples, technologies are employed to reduce the unit area of the three-dimensional transistor and to easily manufacture the metal wiring layer connected to the three-dimensional transistor. Examples of technologies employed to reduce the unit area of the three-dimensional transistor may include multi-gate transistors, advanced lithography techniques, and quantum dot transistors, etc. Examples of technologies employed to easily manufacture a metal wiring layer may include atomic layer deposition (ALD), dual damascene process, and low-k dielectrics, etc. In some cases, stacked transistors, i.e., multiple layers of transistors vertically integrated on top of each other, may increase transistor density while using limited wafer area.

Three-dimensional transistors may use gate-all-around transistors or multi-bridge channel field effect transistors (FETs) to improve gate control and further reduce device size. In some aspects, gate-all-around transistors use horizontal nanosheets that are vertically stacked so that the gate surrounds the channel on all four sides. Additionally, multi-bridge channel FETs are three-dimensional transistors that use multiple channels connected by vertical nanowires. Vertically stacked horizontal nanosheet gate-all-around transistors and multi-bridge channel FETs are considered to be better candidates over fin-structured transistors because the gate structure of a gate-all-around transistor can tune the channel more precisely.

Accordingly, integrated circuit semiconductor device may configure, enable, and manage various technologies to reduce unit area of three-dimensional transistors consists of vertically stacked horizontal nanosheet gate-all-around transistors or multi-bridge channel FETs. For example, in order to continue transistor scaling, multiple gate-all-around transistors or multi-bridge channel FETs may be further stacked vertically by separating the transistors with an isolation insulating layer.

According to some embodiments, an integrated circuit semiconductor device may stack two gate-all-around transistors or multi-bridge channel FETs vertically to reduce unit area. The two stacked transistors may be positioned on two opposite sides of the isolation insulating layer, with the structure of the two stacked transistors positioned in an opposite manner. According to embodiments of the present disclosure, metal wiring layers may be connected to the two stacked transistors at their far ends, away from the isolation insulating layer.

According to some embodiments, a first transistor and a second transistor are stacked vertically and are separated with a transistor isolation insulating layer. According to the present disclosure, the first transistor and the second transistor may be gate-all-around transistors or contact-all-around transistors. In some embodiments, the first transistor and the second transistor may be multi-bridge channel FETs.

In some embodiments, the first transistor is arranged under the transistor isolation insulating layer in an inverse vertical direction, and the second transistor is arranged on the transistor isolation insulating layer in the vertical direction. In some embodiments, the two transistors are the same type (i.e., both N-type transistors or both P-type transistors). In other embodiments, one of the two transistors is N-type transistor, and the other one is P-type transistor. In some embodiments, the second transistor has a higher source and drain area. In some embodiments, the two transistors have source and drain areas of the same height. An integrated circuit semiconductor device described herein may also include a first metal wiring layer connected to a first source and drain of the first transistor and a second metal wiring lay connected to a second source and drain of the second transistor. Accordingly, aspects described herein may result in reduced unit area and easy manufacture of metal wiring layer connected to the transistors.

Certain embodiments of the present disclosure are described in detail with reference to the accompanying drawings. The following embodiments of the present disclosure may be implemented individually, or by combining one or more embodiments. Thus, the technical idea of the present disclosure is not limited to one embodiment. In the present disclosure, the singular forms of the components may include a plurality of forms, unless the context clearly dictates otherwise.

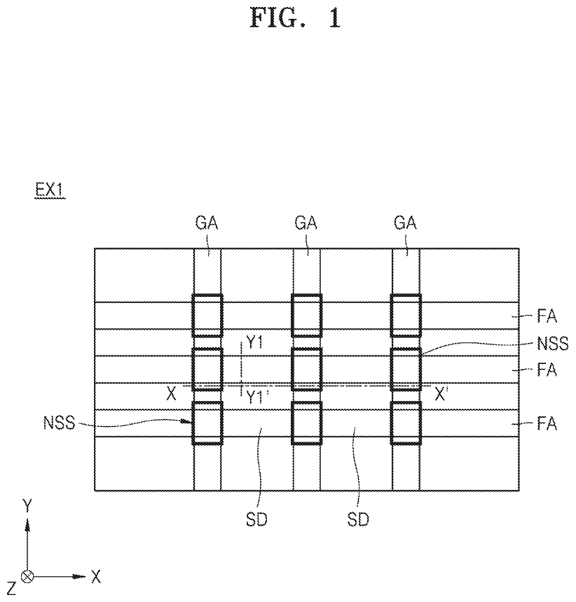

FIG. 1 is a layout diagram of an integrated circuit semiconductor device according to an embodiment.

Specifically, FIG. 1 illustrates an integrated circuit semiconductor device EX1. The integrated circuit semiconductor device EX1 may include active areas FA, nano-sheet stack structures NSS, gate structures GA, and source and drains SD. The active areas FA may extend in a first horizontal direction (X direction) and may be spaced apart from each other in a second horizontal direction (Y direction). The second horizontal direction (Y direction) may be perpendicular to the first horizontal direction (X direction).

The nano-sheet stack structures NSS may be positioned in the active areas FA. The nano-sheet stack structures NSS may be spaced apart from each other in the first horizontal direction(X direction) and the second horizontal direction (Y direction). The nano-sheet stack structures NSS may include semiconductor layers, for example, silicon layers. The gate structures GA may extend in the second horizontal direction (Y direction) in the active areas FA and may be spaced apart from each other in the first horizontal direction (X direction). The source and drains SD may be positioned on both sides of the gate structures GA in the first horizontal direction (X direction). The source and drains SD may be a shared source/drain regions for adjacent two nano-sheet stack structures NSSs in the first horizontal direction (X direction).

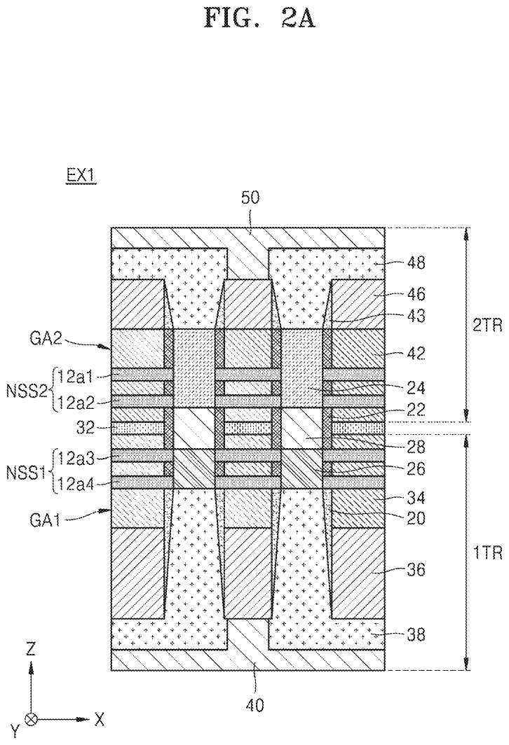

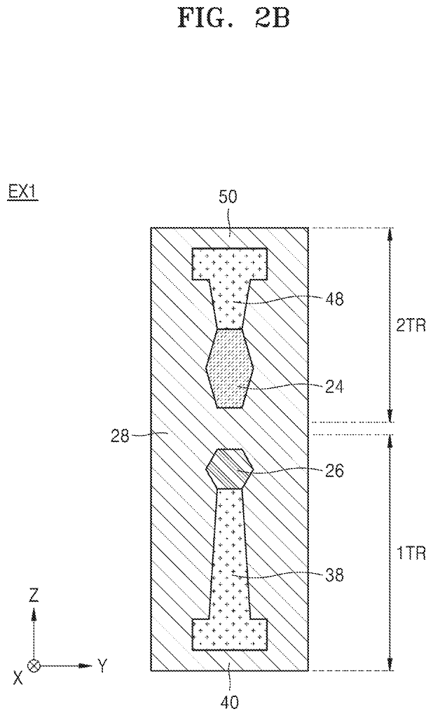

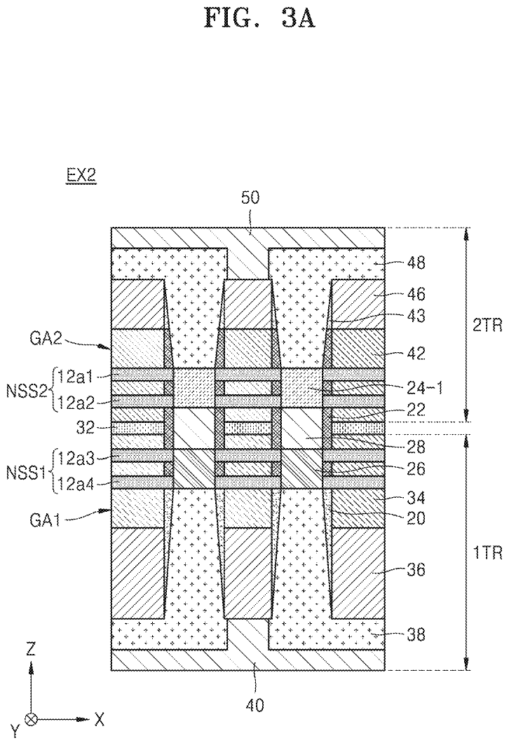

FIGS. 2A and 2B are cross-sectional views of an integrated circuit semiconductor device according to an embodiment.

Specifically, FIG. 2A is a cross-sectional view of the integrated circuit semiconductor device EX1 taken along a line X1-X1′ of FIG. 1, and FIG. 2B is a cross-sectional view of the integrated circuit semiconductor device EX1 taken along a line Y1-Y1′ of FIG. 1. The integrated circuit semiconductor device EX1 may include a first transistor 1TR having a first horizontal direction (X direction), a second horizontal direction (Y direction) perpendicular to the first horizontal direction (X direction), and the vertical direction (Z direction) perpendicular to the first horizontal direction (X direction) and the second horizontal direction (Y direction), and a second transistor 2TR separated from the first transistor 1TR by transistor isolation insulating layers 28 and 32 in the vertical direction (Z direction).

In some embodiments, the first transistor 1TR and the second transistor 2TR may be different types of transistors. For example, the first transistor 1TR may be an N-type transistor and the second transistor 2TR may be a P-type transistor. In some embodiments, the first transistor 1TR and the second transistor 2TR may be the same type of transistors.

The first transistor 1TR may include a first nano-sheet stack structure NSS1 including a plurality of first nano-sheet stacks spaced apart from each other in the first horizontal direction (X direction), where each of the plurality of first nano-sheet stacks comprises a plurality of first nano-sheets 12a3 and 12a4 stacked in the vertical direction (Z direction), first gate structures GA1 and 34 extending in the second horizontal direction (Y direction) and surrounding the first nano-sheet stack structure NSS1, and a first source and drain 26 disposed on both sides of the first nano-sheet stack structure NSS1 in the first horizontal direction (X direction).

The first nano-sheet stack structure NSS1 may correspond to the nano-sheet stack structure NSS of FIG. 1. The first gate structures GA1 and 34 may correspond to the gate structures GA of FIG. 1. The first source and drain 26 may correspond to the source and drain SD of FIG. 1.

The first nano-sheets 12a3 and 12a4 may be spaced apart from each other in the vertical direction (Z direction). The first nano-sheets 12a3 and 12a4 may include semiconductor layers, for example, silicon layers. In some embodiments, two or more first nano-sheets 12a3 and 12a4 may be included. For example, in the integrated circuit semiconductor device EX1, two first nano-sheets 12a3 and 12a4 are included. The thickness of each of the first nano-sheets 12a3 and 12a4 may be several nanometers.

Each of the first gate structures GA1 and 34 may include a first gate insulating layer. The first gate structures GA1 and 34 may be arranged to surround the first nano-sheets 12a3 and 12a4, may be configured to interpose a first gate insulating layer between the first nano-sheets 12a3 and 12a4, and may extend in the second horizontal direction (Y direction). The first gate structures GA1 and 34 may be disposed between the first nano-sheets 12a3 and 12a4 in the vertical direction (Z direction).

The first source and drain 26 may be disposed on both sides of at least one first nano-sheets 12a3 and 12a4 centered on the first gate structures GA1 and 34 in the first horizontal direction (X direction). The first source and drain 26 may include epitaxial layers doped with impurities, e.g., boron, arsenic or phosphorus. The first source and drain 26 may be a silicon epitaxial layer. The first source and drain 26 may be a shared source/drain region for adjacent two of the plurality of first nano-sheet stacks.

An inner spacer 22 may be disposed between the first gate structures GA1 and 34 and the first source and drain 26 in the first horizontal direction (X direction). The inner spacer 22 may include an insulating layer, for example, a silicon oxide layer or a silicon nitride layer. In some embodiments, the inner spacer 22 may or may not be disposed between the first nano-sheets 12a3 and 12a4 and the first source and drain 26 depending on a cutting line. For example, in the integrated circuit semiconductor device EX1, the inner spacer 22 is disposed between the first nano-sheets 12a3 and 12a4 and the first source and drain 26.

The second transistor 2TR may include a second nano-sheet stack structure NSS2 including a plurality of second nano-sheet stacks 12a1 and 12a2 spaced apart from each other in the first horizontal direction (X direction), where each of the plurality of second nano-sheet stacks comprises a plurality of second nano-sheets 12a1 and 12a2 stacked on each other in the vertical direction (Z direction), second gate structures GA2 and 42 extending in the second horizontal direction (Y direction) and surrounding the second nano-sheet stack structure NSS2 in the first horizontal direction (X direction), and a second source and drain 24 disposed on both sides of at least one second nano-sheet stack in the first horizontal direction (X direction).

The second nano-sheet stack structure NSS2 may correspond to the nano-sheet stack structure NSS of FIG. 1. The second gate structures GA2 and 42 may correspond to the gate structure GA of FIG. 1. The second source and drain 24 may correspond to the source and drain SD of FIG. 1.

The second nano-sheets 12a1 and 12a2 may be spaced apart from each other in the vertical direction (Z direction). The second nano-sheets 12a1 and 12a2 may include semiconductor layers, for example, silicon layers. In some embodiments, two or more second nano-sheets 12a1 and 12a2 may be included. For example, in the integrated circuit semiconductor device EX1, two second nano-sheets 12a1 and 12a2 are included. The thickness of each of the second nano-sheets 12a1 and 12a2 may be several nanometers.

The second gate structures GA2 and 42 may include a second gate insulating layer. The second gate structures GA2 and 42 may be arranged to surround the second nano-sheets 12a1 and 12a2, may be configured to interpose a second gate insulating layer between the second nano-sheets 12a1 and 12a2, and may extend in the second horizontal direction (Y direction). The second gate structures GA2 and 42 may be disposed between the second nano-sheets 12a1 and 12a2 in the vertical direction (Z direction).

The second source and drain 24 may be disposed on both sides of at least one second nano-sheets 12a1 and 12a2 centered on the second gate structures GA2 and 42 in the first horizontal direction (X direction). The second source and drain 24 may include epitaxial layers doped with impurities, e.g., boron, arsenic or phosphorus. The second source and drain 24 may be a silicon epitaxial layer. The second source and drain 24 may be a shared source/drain region for adjacent two of the plurality of second nano-sheet stacks. The height of the second source and drain 24 may be greater than the height in the vertical direction (Z direction) than the first source and drain 26, as shown in FIGS. 2A and 2B.

An inner spacer 22 may also be disposed between the second gate structures GA2 and 42 and the second source and drain 24 in the first horizontal direction (X direction). The inner spacer 22 may be disposed on both sidewalls of the first gate structures GA1 and 34, the second gate structures GA2 and 42, and the transistor isolation insulating layers 28 and 32. In some embodiments, the inner spacer 22 may or may not be disposed between the second nano-sheets 12a1 and 12a2 and the second source and drain 24 depending on a cutting line. For example, in the integrated circuit semiconductor device EX1, the inner spacer 22 are disposed between the second nano-sheets 12a1 and 12a2 and the second source and drain 24

In the first transistor 1TR, the first length of the first nano-sheets 12a3 and 12a4 in the first horizontal direction (X direction) may be a first channel length. In the second transistor 2TR, the second length of the second nano-sheets 12a1 and 12a2 in the first horizontal direction (X direction) may be a second channel length. In some embodiments, the first channel length and the second channel length may be same or different. For example, the first channel length may be greater than the second channel length.

The first transistor 1TR may be a three-dimensional transistor including the first nano-sheet stack structure NSS1, the first gate structures GA1 and 34, and the first source and drain 26. The second transistor 2TR may be a three-dimensional transistor including the second nano-sheet stack structure NSS2, the second gate structures GA2 and 42, and the second source and drain 24.

The first transistor 1TR and the second transistor 2TR may be a gate all around transistor or a contact all around transistor. The first transistor 1TR and the second transistor 2TR may be multi-bridge channel field effect transistors (FETs).

The transistor isolation insulating layers 28 and 32 may include a source and drain isolation insulating layer 28 for separating the first source and drain 26 and the second source and drain 24 from each other in the vertical direction (Z direction), as shown in FIGS. 2A and 2B. The transistor isolation insulating layers 28 and 32 may include a gate isolation insulating layer 32 for separating the first gate structures GA1 and 34 and the second gate structures GA2 and 42 in the vertical direction (Z direction).

The integrated circuit semiconductor device EX1 may have a symmetric structure in the vertical direction (Z direction) on the basis of the transistor isolation insulating layers 28 and 32. When viewed based on the transistor isolation insulating layers 28 and 32, the first transistor 1TR may be arranged under the transistor isolation insulating layers 28 and 32 in the inverse vertical direction (−Z direction).

The first transistor 1TR may include a first nano-sheet stack structure NSS1 including a plurality of first nano-sheet stacks spaced apart from each other in the first horizontal direction (X direction), where each of the plurality of first nano-sheet stacks comprises a plurality of first nano-sheets 12a3 and 12a4 stacked in the inverse vertical direction (−Z direction), first gate structures GA1 and 34 extending in the second horizontal direction (Y direction) and surrounding the first nano-sheet stack structure NSS1, and a first source and drain 26 disposed on both sides of the first nano-sheet stack structure NSS1 in the first horizontal direction (X direction). The second transistor 2TR may be arranged on the transistor isolation insulating layers 28 and 32 in the vertical direction (Z direction).

The integrated circuit semiconductor device EX1 may further include a first hard mask 36 disposed under the first gate structures GA1 and 34 in the inverse vertical direction (−Z direction). The first hard mask 36 may include an insulating layer. The integrated circuit semiconductor device EX1 may further include a first metal wiring layer 38 connected to the first source and drain 26 in the inverse vertical direction (−Z direction). The first metal wiring layer 38 may include metal, conductive metal nitride, or a combination thereof, or other materials. The first metal wiring layer 38 may include tungsten (W), copper (Cu), aluminum (Al), titanium (Ti), tantalum (Ta), titanium nitride (TiN), tantalum nitride (TaN), molybdenum phosphorus composite (MoP), an alloy thereof, or a combination thereof, or other materials.

The first metal wiring layer 38 may be disposed on the first hard mask 36 and may extend in the first horizontal direction (X direction). A first outer spacer 20 may be disposed on inner walls of the first gate structures GA1 and 34 and the first hard mask 36. The first outer spacer 20 may include an insulating layer. The first metal wiring layer 38 may be insulated by the first wiring insulating layer 40.

The integrated circuit semiconductor device EX1 may further include a second hard mask 46 disposed on the second gate structures GA2 and 42 in the vertical direction (Z direction). The second hard mask 46 may include an insulating layer. The integrated circuit semiconductor device EX1 may further include a second metal wiring layer 48 connected to the second source and drain 24 in the vertical direction (Z direction). The second metal wiring layer 48 may include metal, conductive metal nitride, or a combination thereof, or other materials. The second metal wiring layer 48 may include W, Cu, Al, Ti, Ta, TiN, TaN, MoP, an alloy thereof, or a combination thereof, or other materials.

The second metal wiring layer 48 may be disposed on the second hard mask 46 and may extend in the first horizontal direction (X direction). A second outer spacer 43 may be disposed on inner walls of the second gate structures GA2 and 42 and the second hard mask 46. The second outer spacer 43 may include an insulating layer. The second metal wiring layer 48 may be insulated by the second wiring insulating layer 50.

The integrated circuit semiconductor device EX1 described above may include three-dimensional first and second transistors 1TR and 2TR separated from each other by the transistor isolation insulating layers 28 and 32 in the vertical direction (Z direction), and first and second metal wiring layers 38 and 48 connected to the first and second transistors 1TR and 2TR, respectively.

Thus, in some embodiments of the present disclosure, a device unit area may be reduced by integrating (e.g., stacking) the three-dimensional first and second transistors 1TR and 2TR in the vertical direction (Z direction). Furthermore, in some embodiments of the present disclosure, the first and second metal wiring layers 38 and 48 may be directly and easily connected to the three-dimensional first and second transistors 1TR and 2TR, respectively.

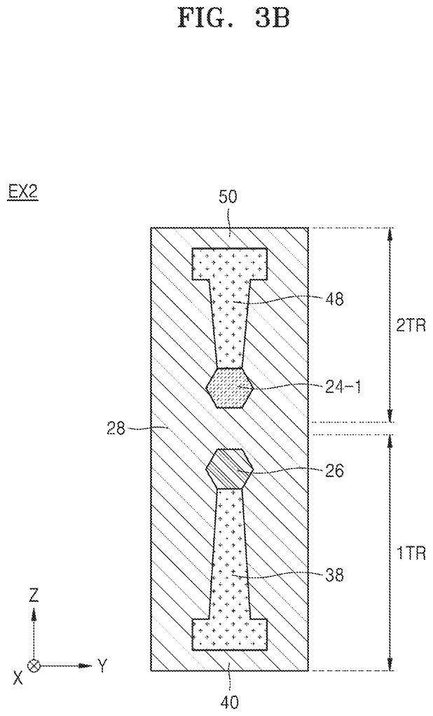

FIGS. 3A and 3B are cross-sectional views of an integrated circuit semiconductor device according to an example embodiment.

Specifically, FIGS. 2A and 2B are cross-sectional views of an integrated circuit semiconductor device EX2. The integrated circuit semiconductor device is similar to the integrated circuit semiconductor device EX1 of FIGS. 1, 2A, and 2B and is different from the integrated circuit semiconductor device EX2 in the configuration of a second source and drain 24-1 when compared to the integrated circuit semiconductor device EX1 of FIGS. 1, 2A, and 2B. In FIGS. 3A and 3B, descriptions given with reference to FIGS. 1, 2A, and 2B are briefly given or omitted.

The integrated circuit semiconductor device EX2 may include first and second transistors 1TR and 2TR spaced apart from each other by the transistor isolation insulating layers 28 and 32 in the vertical direction (Z direction). The first transistor 1TR may include a first nano-sheet stack structure NSS1 including first nano-sheets 12a3 and 12a4, first gate structures GA1 and 34, and a first source and drain 26.

The second transistor 2TR may include a second nano-sheet stack structure NSS2 including second nano-sheets 12a1 and 12a2, second gate structures GA2 and 42, and a second source and drain 24-1. As shown in FIGS. 3A and 3B, the height of the second source and drain 24-1 may be the same as the height of the first source and drain 26 in the vertical direction (Z direction).

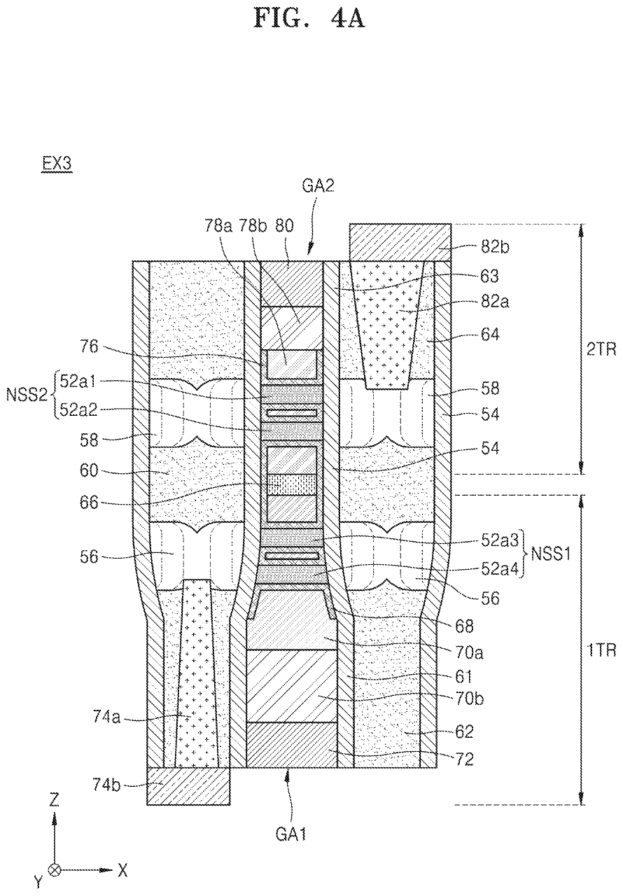

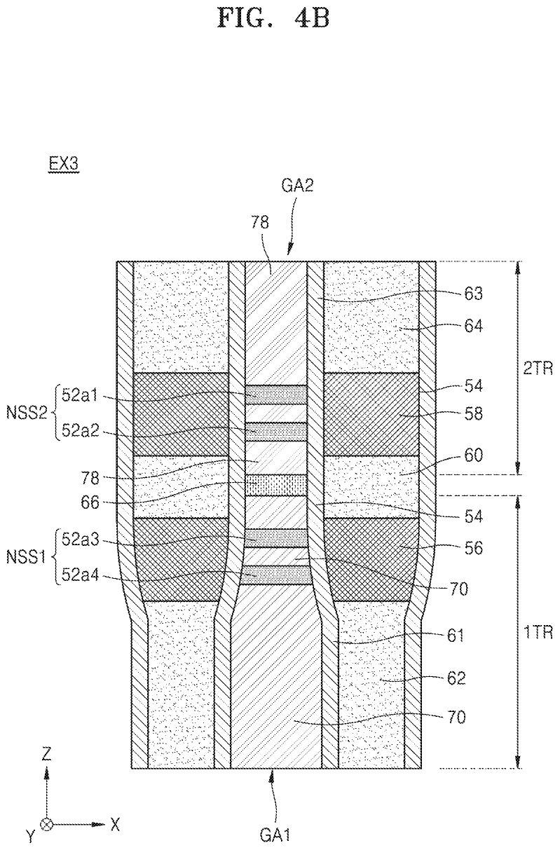

FIGS. 4A and 4B are cross-sectional views of an integrated circuit semiconductor device according to an example embodiment.

Specifically, FIG. 4A is a cross-sectional view of an integrated circuit semiconductor device EX3. FIG. 4B illustrates a partial region of the integrated circuit semiconductor device EX3 by simplifying the integrated circuit semiconductor device EX3 of FIG. 4A for convenience of description. In FIGS. 4A and 4B, the same or similar descriptions given with reference to FIGS. 1, 2A, and 2B are briefly given or omitted.

The integrated circuit semiconductor device EX3 may include a first transistor 1TR having a first horizontal direction (X direction), a second horizontal direction (Y direction) perpendicular to the first horizontal direction (X direction), and the vertical direction (Z direction) perpendicular to the first horizontal direction (X direction) and the second horizontal direction (Y direction), and a second transistor 2TR separated from the first transistor 1TR by transistor isolation insulating layers 60 and 66 in the vertical direction (Z direction).

In some embodiments, the first transistor 1TR and the second transistor 2TR may be different types of transistors. For example, the first transistor 1TR may be an N-type transistor, and the second transistor 2TR may be a P-type transistor. In some embodiments, the first transistor 1TR and the second transistor 2TR may be the same type of transistors.

The first transistor 1TR may include a first nano-sheet stack structure NSS1 including a plurality of first nano-sheet stacks spaced apart from each other in the first horizontal direction (X direction), where each of the plurality of first nano-sheet stacks comprises a plurality of first nano-sheets 52a3 and 52a4 stacked in the vertical direction (Z direction), first gate structures GA1, 68, 70a, and 70b extending in the second horizontal direction (Y direction) and surrounding the first nano-sheet stack structure NSS1, and a first source and drain 56 disposed on both sides of at least one first nano-sheet stack structure NSS1 in the first horizontal direction (X direction).

The first nano-sheet stack structure NSS1 may correspond to the nano-sheet stack structure NSS of FIG. 1. The first gate structures GA1, 68, 70a, and 70b may correspond to the gate structure GA of FIG. 1. The first source and drain 56 may correspond to the source and drain SD of FIG. 1.

The first nano-sheets 52a3 and 52a4 may be spaced apart from each other in the vertical direction (Z direction). The first nano-sheets 52a3 and 52a4 may include semiconductor layers, for example, silicon layers. In some embodiments, two or more first nano-sheets 52a3 and 52a4 may be included. For example, in the integrated circuit semiconductor device EX3, two first nano-sheets 52a3 and 52a4 are included. The thickness of each of the first nano-sheets 52a3 and 52a4 may be several nanometers.

The first gate structures GA1, 68, 70a, and 70b may include a first gate insulating layer 68 and first gate metal layers 70a and 70b. The first gate insulating layer 68 may be a high-k dielectric layer, for example, a hafnium oxide layer. The first gate metal layers 70a and 70b may include a first sub-gate metal layer 70a and a second sub-gate metal layer 70b. The first sub-gate metal layer 70a may include a metal layer for adjusting a threshold voltage, for example, TiN, TaN, or the like and the second sub-gate metal layer 70b may include a metal layer having a low resistance, for example, tungsten (W), etc. Referring to FIG. 4B, the first gate metal layers 70a and 70b are denoted by reference numeral 70.

The first gate structures GA1, 68, 70a, and 70b may extend in the second horizontal direction (Y direction) and surround the first nano-sheets 52a3 and 52a4. The first gate structures GA1, 68, 70a, and 70b may be disposed between the first nano-sheets 52a3 and 52a4 in the vertical direction (Z direction) by interposing the first gate insulating layer 68 between the first gate structures GA1, 68, 70a, and 70b. The first gate insulating layer 68 may not be disposed on both sidewalls or on an upper portion of the second sub-gate metal layer 70b. The first gate insulating layer 68 may surround the first sub-gate metal layer 70a or may be disposed on both sidewalls and on an upper portion of the first sub-gate metal layer 70a.

The first source and drain 56 may be disposed on both sides of at least one first nano-sheets 52a3 and 52a4 in the first horizontal direction (X direction). The first source and drain 56 may include an epitaxial layer doped with impurities, e.g., boron, arsenic or phosphorus. In some embodiments, an impurity concentration level of the first source and drain 56 vary inside, as indicated by the dashed line of FIG. 4A. The first source and drain 56 may have an upper length greater than a lower length of the first source and drain 56 in the first horizontal direction (X direction).

An inner spacer 54 may be disposed between the first gate structures GA1, 68, 70a, and 70b and the first source and drain 56 in the first horizontal direction (X direction). The inner spacer 54 may include an insulating layer, for example, a silicon oxide layer or a silicon nitride layer. In some embodiments, the inner spacer 54 may or may not be disposed between the first nano-sheets 52a3 and 52a4 and the first source and drain 56 depending on a cutting line. For example, in the integrated circuit semiconductor device EX3, the inner spacer 54 are disposed between the first nano-sheets 52a3 and 52a4 and the first source and drain 56.

The second transistor 2TR may include a second nano-sheet stack structure NSS2 including a plurality of second nano-sheet stacks spaced apart from each other in the first horizontal direction (X direction), where each of the plurality of second nano-sheet stacks comprises a plurality of second nano-sheets 52a3 and 52a4 stacked in the vertical direction (Z direction), second gate structures GA2, 76, 78a, and 78b extending in the second horizontal direction (Y direction) and surrounding the second nano-sheet stack structure NSS2, and a second source and drain 58 disposed on both sides of at least one second nano-sheet stack structure NSS2 in the first horizontal direction (X direction).

The second nano-sheet stack structure NSS2 may correspond to the nano-sheet stack structure NSS of FIG. 1. The second gate structures GA2, 76, 78a, and 78b may correspond to the gate structure GA of FIG. 1. The second source and drain 58 may correspond to the source and drain SD of FIG. 1.

The second nano-sheets 52a1 and 52a2 may be spaced apart from each other in the vertical direction (Z direction). The second nano-sheets 52a1 and 52a2 may include semiconductor layers, for example, silicon layers. In some embodiments, two or more second nano-sheets 52a1 and 52a2 are included. For example, in the integrated circuit semiconductor device EX3, two second nano-sheets 52a1 and 52a2 are included. The thickness of each of the second nano-sheets 52a1 and 52a2 may be several nanometers.

The second gate structures GA2, 76, 78a, and 78b may include a second gate insulating layer 76 and second gate metal layers 78a and 78b. The second gate insulating layer 76 may be a high-k dielectric layer, for example, a hafnium oxide layer. The second gate metal layers 78a and 78b may include a third sub-gate metal layer 78a and a fourth sub-gate metal layer 78b. The third sub-gate metal layer 78a may include a metal layer for adjusting a threshold voltage, for example, TiN, TaN, or the like and the fourth sub-gate metal layer 78b may include a metal layer having a low resistance, for example, tungsten (W), etc. Referring to FIG. 4B, the second gate metal layers 78a and 78b are denoted by reference numeral 78.

The second gate structures GA2, 76, 78a, and 78b may extend in the second horizontal direction (Y direction) and surround the second nano-sheets 52a1 and 52a2. The second gate structures GA2, 76, 78a, and 78b may be disposed between the second nano-sheets 52a1 and 52a2 in the vertical direction (Z direction) by interposing the second gate insulating layer 76 between the second gate structures GA2, 76, 78a, and 78b. The second gate insulating layer 76 may not be disposed on both sidewalls or on an upper portion of the fourth sub-gate metal layer 78b. The second gate insulating layer 76 may surround the third sub-gate metal layer 78a or may be disposed on both sidewalls or on an upper portion of the third sub-gate metal layer 78a.

The second source and drain 58 may be disposed on both sides of at least one second nano-sheets 52a1 and 52a2 in the first horizontal direction (X direction). The second source and drain 58 may include an epitaxial layer doped with impurities, e.g., boron, arsenic or phosphorus. In some embodiments, an impurity concentration level of the second source and drain 58 vary inside, as indicated by the dashed line of FIG. 4A.

The height of the second source and drain 58 may be the same as the height of the first source and drain 56 in the vertical direction (Z direction), as shown in FIGS. 4A and 4B. The width of the second gate structures GA2, 76, 78a, and 78b in the first horizontal direction (X direction) may be greater than the width of the first gate structures GA1, 68, 70a, and 70b.

An inner spacer 54 may be disposed between the second gate structures GA2, 76, 78a, and 78b and the second source and drain 58 in the first horizontal direction (X direction). The inner spacer 54 may be disposed on both sides of the first gate structures GA1, 68, 70a, and 70b, the second gate structures GA2, 76, 78a, and 78b, and the transistor isolation insulating layers 60 and 66. In some embodiments, the inner spacer 54 may or may not be disposed between the second nano-sheets 52a1 and 52a2 and the second source and drain 58 depending on a cutting line. For example, in the integrated circuit semiconductor device EX3, the inner spacer 54 are disposed between the second nano-sheets 52a1 and 52a2 and the second source and drain 58.

In the first transistor 1TR, the first length of the first nano-sheets 52a3 and 52a4 in the first horizontal direction (X direction) may be a first channel length. In the second transistor 2TR, the second length of the second nano-sheets 52a1 and 52a2 in the first horizontal direction (X direction) may be a second channel length. In some embodiments, the first channel length may be greater than the second channel length.

The first transistor 1TR may be a three-dimensional transistor including the first nano-sheet stack structure NSS1, the first gate structures GA1, 68, 70a, and 70b, and the first source and drain 56. The second transistor 2TR may be a three-dimensional transistor including the second nano-sheet stack structure NSS2, the second gate structures GA2, 76, 78a, and 78b, and the second source and drain 58.

The first transistor 1TR and the second transistor 2TR may be a gate all around transistor or a contact all around transistor. The first transistor 1TR and the second transistor 2TR may be multi-bridge channel FETs.

The transistor isolation insulating layers 60 and 66 may include a source and drain isolation insulating layer 60 for separating the first source and drain 56 and the second source and drain 58 from each other in the vertical direction (Z direction), as shown in FIGS. 4A and 4B. The transistor isolation insulating layers 60 and 66 may include a gate isolation insulating layer 66 for separating the first gate structures GA1, 68, 70a, and 70b and the second gate structures GA2, 76, 78a, and 78b in the vertical direction (Z direction).

At a level of the gate isolation insulating layer 66 of FIG. 4A, a first gate insulating layer 68 constituting first gate structures GA1, 68, 70a, and 70b and a second gate insulating layer 76 constituting second gate structures GA2, 76, 78a, and 78b may be connected to each other in the vertical direction (Z direction).

The integrated circuit semiconductor device EX3 may have a symmetric structure in the vertical direction (Z direction) on the basis of the transistor isolation insulating layers 60 and 66. When viewed based on the transistor isolation insulating layers 60 and 66, the first transistor 1TR may be arranged under the transistor isolation insulating layers 60 and 66 in an inverse vertical direction (−Z direction).

The first transistor 1TR may include a first nano-sheet stack structure NSS1 including a plurality of first nano-sheet stacks spaced apart from each other in the first horizontal direction (X direction), where each of the plurality of first nano-sheet stacks comprises a plurality of first nano-sheets 52a3 and 52a4 stacked in the inverse vertical direction (−Z direction), first gate structures GA1, 68, 70a, and 70b extending in the second horizontal direction (Y direction) and surrounding the first nano-sheet stack structure NSS1, and a first source and drain 56 disposed on both sides of at least one first nano-sheet stack structure NSS1 in the first horizontal direction (X direction). The second transistor 2TR may be arranged on the transistor isolation insulating layers 60 and 66 in the vertical direction (Z direction).

The integrated circuit semiconductor device EX3 may further include a first hard mask 72 disposed under the first gate structures GA1, 68, 70a, and 70b in the inverse vertical direction (−Z direction). The first hard mask 72 may include an insulating layer. The integrated circuit semiconductor device EX3 may further include first metal wiring layers 74a and 74b connected to the first source and drain 56 in the inverse vertical direction (−Z direction).

The first metal wiring layers 74a and 74b may extend in the first horizontal direction (X direction). A first outer spacer 61 may be disposed on inner walls of the first gate structures GA1, 68, 70a, and 70b. The first outer spacer 61 may include an insulating layer. The first metal wiring layers 74a and 74b may be insulated by the first wiring insulating layer 62. In the integrated circuit semiconductor device EX3, the first outer spacer 61, the inner spacer 54, and the second outer spacer 63 may extend in the vertical direction (Z direction) and may be connected to each other.

The integrated circuit semiconductor device EX3 may further include a second hard mask 80 disposed on the second gate structures GA2, 76, 78a, and 78b in the vertical direction (Z direction). The second hard mask 80 may include an insulating layer. The integrated circuit semiconductor device EX3 may further include second metal wiring layers 82a and 82b connected to the second source and drain 58 in the vertical direction (Z direction).

The second metal wiring layers 82a and 82b may extend in the first horizontal direction (X direction). A second outer spacer 63 may be disposed on inner walls of the second gate structures GA2, 76, 78a, and 78b. The second outer spacer 63 may include an insulating layer. The second metal wiring layers 82a and 82b may be insulated by the second wiring insulating layer 64.

The integrated circuit semiconductor device EX3 described above may include three-dimensional first and second transistors 1TR and 2TR separated from each other by the transistor isolation insulating layers 60 and 66 in the vertical direction (Z direction), and first and second metal wiring layers 74a, 74b, 82a, and 82b connected to the first and second transistors 1TR and 2TR, respectively.

Thus, in some embodiments of the present disclosure, a device unit area may be reduced by integrating (e.g., stacking) the three-dimensional first and second transistors 1TR and 2TR in the vertical direction (Z direction). Furthermore, in some embodiments of the present disclosure, the first and second metal wiring layers 74a, 74b, 82a, and 82b may be directly and easily connected to the three-dimensional first and second transistors 1TR and 2TR, respectively.

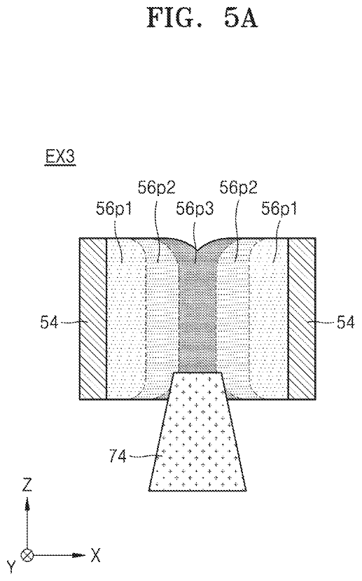

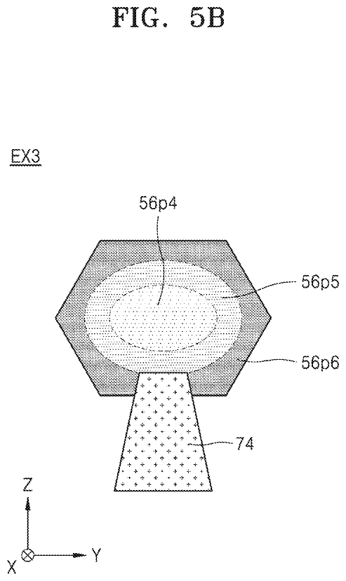

FIGS. 5A and 5B are cross-sectional views illustrating an impurity concentration level of a first source and drain of the integrated circuit semiconductor device EX3 of FIG. 4A.

Specifically, FIG. 5A illustrates an impurity concentration level of the first source and drain (56 in FIG. 4A) in the first horizontal direction (X direction). The first source and drain (56 in FIG. 4A) has a higher impurity concentration inside than outside in the first horizontal direction (X direction). As shown in FIG. 5A, the impurity concentration of the first source and drain (56 in FIG. 4A) in the first horizontal direction (X direction) is high in a central portion 56p3 and is low in peripheral portions 56p1 and 56p2. In other words, the impurity concentration of the first source and drain (56 in FIG. 4A) gradually increases from the inner spacer 54 to the central portion 56p3 in the first horizontal direction (X direction).

FIG. 5B illustrates an impurity concentration level of the first source and drain (56 in FIG. 4A) in the second horizontal direction (Y direction). The first source and drain (56 in FIG. 4A) has a lower impurity concentration inside than outside in the second horizontal direction (Y direction). As shown in FIG. 5B, the impurity concentration of the first source and drain (56 in FIG. 4A) in the second horizontal direction (Y direction) is low in a central portion 56p4 and is high in peripheral portions 56p5 and 56p6. In other words, the impurity concentration of the first source and drain (56 in FIG. 4A) gradually increases from the inside to the outside in the second horizontal direction (Y direction).

In FIGS. 5A and 5B, reference numeral 74 represents first metal wiring layers 74a and 74b. The impurity concentration levels of the first source and drain (56 in FIG. 4A) of FIGS. 5A and 5B may be equally applied to the second source and drain (58 of FIG. 4A) of FIG. 4A.

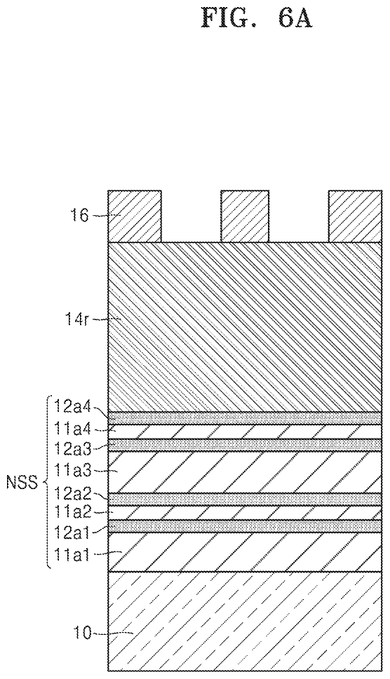

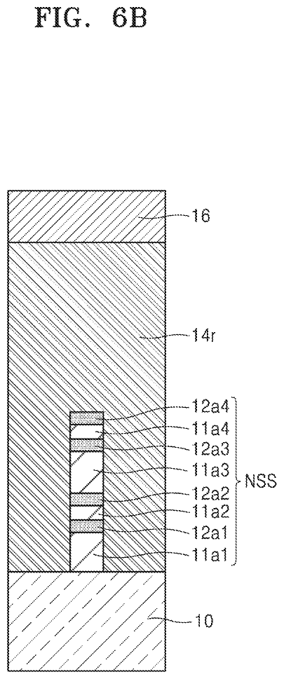

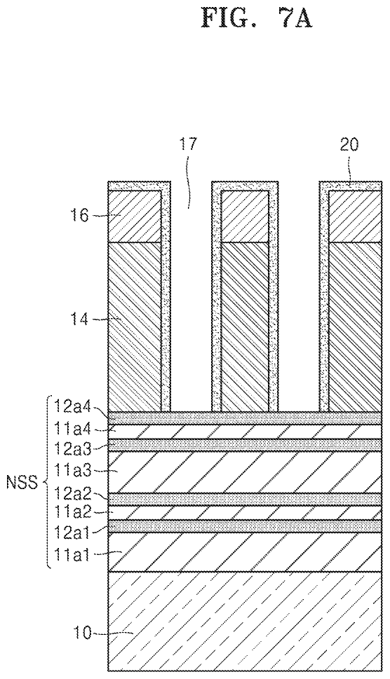

FIGS. 6A through 16B are cross-sectional views for describing a method of manufacturing the integrated circuit semiconductor device EX1 of FIGS. 1, 2A, and 2B.

Specifically, FIGS. 6A through 16A illustrate a method of manufacturing the integrated circuit semiconductor device EX1 of FIG. 2A, and cross-sectional views are taken along a line X1-X1′ of FIG. 1. FIGS. 6B through 16B illustrate a method of manufacturing the integrated circuit semiconductor device EX1 of FIG. 2B, and cross-sectional views are taken along a line Y1-Y1′ of FIG. 1. In FIGS. 6A through 16B, descriptions given with reference to FIGS. 1, 2A, and 2B are briefly given or omitted.

Referring to FIGS. 6A and 6B, a nano-sheet stack structure NSS may be formed by sequentially stacking a first sacrificial semiconductor layer 11a1, a first semiconductor layer 12a1 for nano-sheets, a second sacrificial semiconductor layer 11a2, a second semiconductor layer 12a2 for nano-sheets, a third sacrificial semiconductor layer 11a3, a third semiconductor layer 12a3 for nano-sheets, a fourth sacrificial semiconductor layer 11a4, and a fourth semiconductor layer 12a4 for nano-sheets.

The nano-sheet stack structure NSS may be formed by alternately stacking the sacrificial semiconductor layers 11a1, 11a2, 11a3, and 11a4 and semiconductor layers 12a1, 12a2, 12a3, and 12a4 for nano-sheets. In some embodiments, four or more sacrificial semiconductor layers 11a1, 11a2, 11a3, and 11a4 and four or more semiconductor layers 12a1, 12a2, 12a3, and 12a4 for nano-sheets are formed on the nano-sheet stack structure NSS.

The sacrificial semiconductor layers 11a1, 11a2, 11a3, and 11a4 and the semiconductor layers 12a1, 12a2, 12a3, and 12a4 for nano-sheets may be formed through an epitaxial growth method. The sacrificial semiconductor layers 11a1, 11a2, 11a3, and 11a4 and the semiconductor layers 12a1, 12a2, 12a3, and 12a4 for nano-sheets may include different materials.

In some embodiments, the sacrificial semiconductor layers 11a1, 11a2, 11a3, and 11a4 are made of silicon germanium (SiGe) or other materials, and the semiconductor layers 12a1, 12a2, 12a3, and 12a4 for the nano-sheets may be made of Si or other materials. The sacrificial semiconductor layers 11a1, 11a2, 11a3, and 11a4 may include materials which may be easier to etch comparing to the semiconductor layers 12a1, 12a2, 12a3, and 12a4 for nano-sheets.

The thicknesses of the first sacrificial semiconductor layer 11a1 and the third sacrificial semiconductor layer 11a3 may be greater than the thicknesses of the first semiconductor layer 12a1, the second sacrificial semiconductor layer 11a2, the second semiconductor layer 12a2 for nano-sheets, the third semiconductor layer 12a3 for nano-sheets, the fourth sacrificial semiconductor layer 11a4, and the fourth semiconductor layer 12a4 for nano-sheets.

The first semiconductor layer 12a1, the second sacrificial semiconductor layer 11a2, the second semiconductor layer 12a2 for nano-sheets, the third semiconductor layer 12a3 for nano-sheets, the fourth sacrificial semiconductor layer 11a4, and the fourth semiconductor layer 12a4 for nano-sheets may have the same or different thickness.

In FIG. 6B, the nano-sheet stack structure NSS may be device-isolated and patterned. In other words, FIG. 6B is a cross-sectional view taken along a line Y1-Y1′ of FIG. 1, and thus, the nano-sheet stack structure NSS may be formed on a partial region of the substrate 10.

A dummy gate material layer 14r and mask patterns 16 may be formed on the nano-sheet stack structure NSS. The dummy gate material layer 14r may include a silicon layer. As shown in FIG. 6A, the mask patterns 16 may be spaced apart from each other on the dummy gate material layer 14r. The mask patterns 16 may include a hard mask pattern. The mask patterns 16 may include silicon nitride, polysilicon, a spin-on hard mask (SOH) material, or a combination thereof, or other materials.

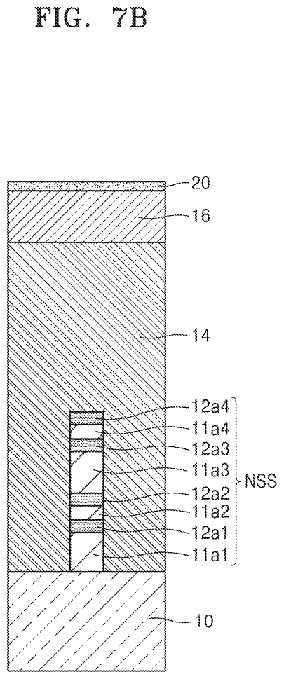

Referring to FIGS. 7A and 7B, dummy gates 14 may be formed by selectively etching the dummy gate material layer (14r in FIGS. 6A and 6B) by using the mask patterns 16 as an etching mask. As shown in FIG. 7A, a first opening 17 may be formed between the dummy gates 14 on the nano-sheet stack structure NSS.

Subsequently, a first outer spacer 20 may be formed on sidewalls of the first opening 17 and the mask patterns 16. The first outer spacer 20 may include an insulating layer.

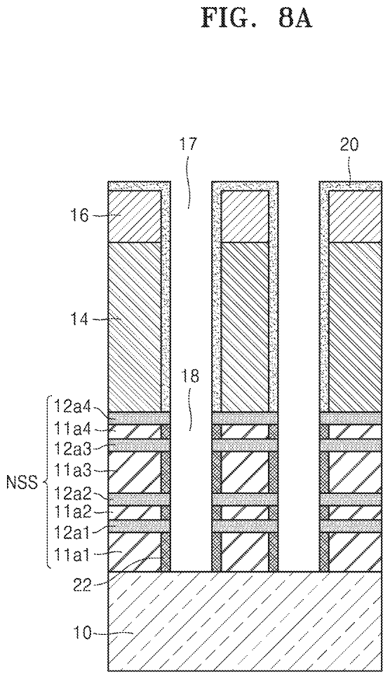

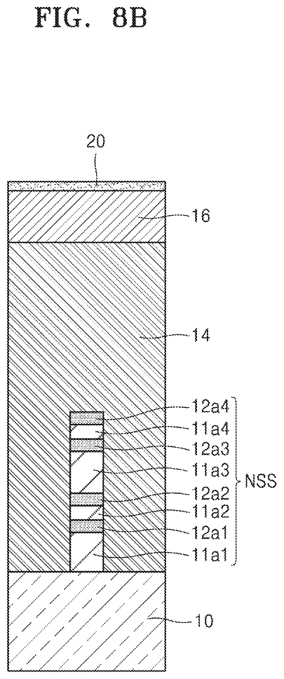

Referring to FIGS. 8A and 8B, the nano-sheet stack structure NSS may be selectively etched by using the dummy gates 14, the mask patterns 16, and the first outer spacer 20 as an etching mask. The fourth semiconductor layer 12a4 for nano-sheets, the fourth sacrificial semiconductor layer 11a4, the third semiconductor layer 12a3 for nano-sheets, the third sacrificial semiconductor layer 11a3, the second semiconductor layer 12a2 for nano-sheets, the second sacrificial semiconductor layer 11a2, the first semiconductor layer 12a1 for nano-sheets, and the first sacrificial semiconductor layer 11a1 may be sequentially etched by using the dummy gates 14, the mask patterns 16, and the first outer spacer 20 as an etching mask.

Then, a second opening 18 may be formed in the nano-sheet stack structure NSS. The second opening 18 may communicate with the first opening (17 in FIG. 7A). The bottom of the second opening 18 may be the surface of the substrate 10.

Subsequently, an inner spacer 22 may be selectively formed on both sides of the fourth sacrificial semiconductor layer 11a4, the third sacrificial semiconductor layer 11a3, the second sacrificial semiconductor layer 11a2, and the first sacrificial semiconductor layer 11a1 in the second opening 18. The inner spacer 22 may include an insulating layer, for example, an oxide layer.

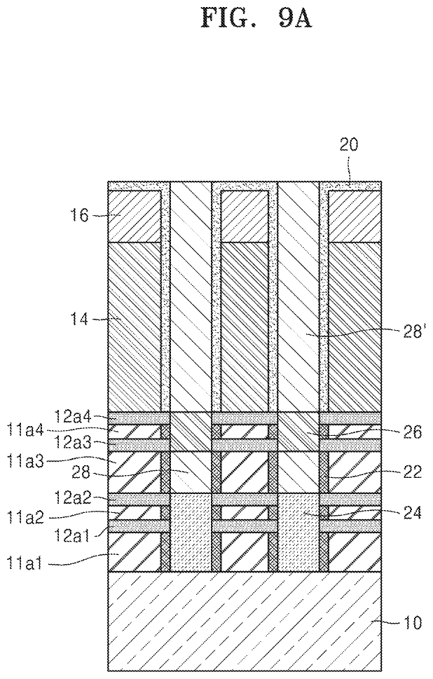

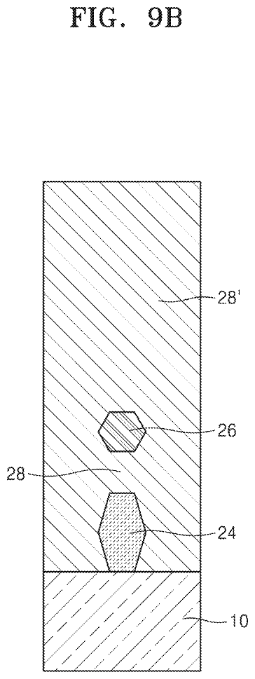

Referring to FIGS. 9A and 9B, a first source and drain 26, a second source and drain 24, and a transistor isolation insulating layer 28 may be formed in the second opening (18 in FIG. 8A). A first insulating layer 28′ may be formed in the first opening (17 in FIG. 8A). The transistor isolation insulating layer 28 and the first insulating layer 28′ may be simultaneously formed. The transistor isolation insulating layer 28 and the first insulating layer 28′ may include an oxide layer.

The first source and drain 26 and the second source and drain 24 may be epitaxial layers formed through an epitaxial growth method. The first source and drain 26 may be an epitaxial layer that is epitaxially-grown from both sidewalls of the fourth semiconductor layer 12a4 for nano-sheets and the third semiconductor layer 12a3 for nano-sheets. The second source and drain 24 may be an epitaxial layer that is epitaxially-grown from both sidewalls of the first semiconductor layer 12a1 for nano-sheets and the second semiconductor layer 12a2 for nano-sheets.

The first source and drain 26 and the second source and drain 24 may be simultaneously formed. The first source and drain 26 and the second source and drain 24 may be silicon epitaxial layers. A transistor isolation insulating layer 28 for separating the first source and drain 26 and the second source and drain 24 in the vertical direction (Z direction) may also be referred to as a source and drain isolation insulating layer.

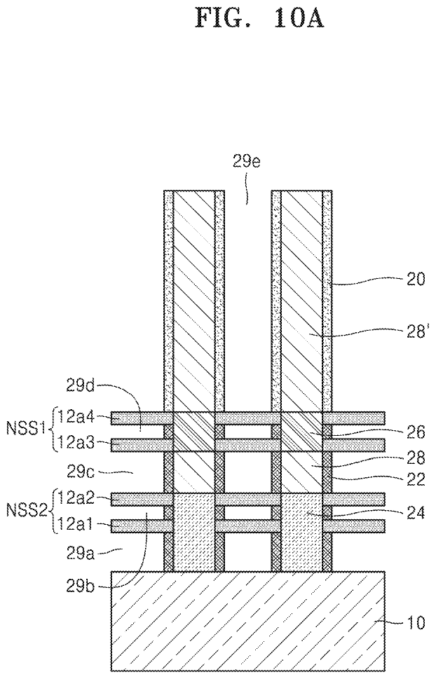

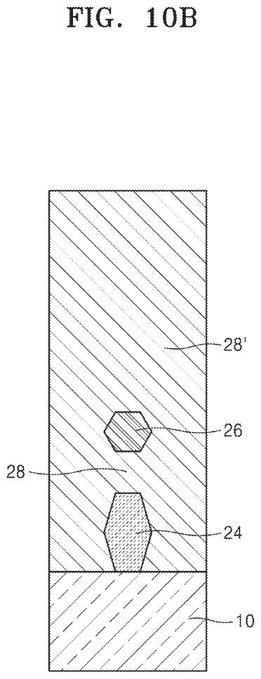

Referring to FIGS. 10A and 10B, the mask patterns (16 in FIG. 9A) and the dummy gates 14 may be removed by using the first insulating layer 28′ and the first outer spacer 20 as a mask. Subsequently, the fourth sacrificial semiconductor layer (11a4 in FIG. 9A), the third sacrificial semiconductor layer (11a3 in FIG. 9A), the second sacrificial semiconductor layer (11a2 in FIG. 9A), and the first sacrificial semiconductor layer (11a1 in FIG. 9A) may be sequentially removed by using the first insulating layer 28′ and the first outer spacer 20 as a mask. In the previous removal process, the first outer spacer 20 formed on the upper surface of the first insulating layer 28′ may be etched.

In this case, a first nano-sheet stack structure NSS1 including the third semiconductor layer 12a3 for nano-sheets and the fourth semiconductor layer 12a4 for nano-sheets may be formed on both sides of the first source and drain 26. The third semiconductor layer 12a3 for nano-sheets and the fourth semiconductor layer 12a4 for nano-sheets may also be referred to as first nano-sheets 12a3 and 12a4.

A second nano-sheet stack structure NSS2 including the first semiconductor layer 12a1 for nano-sheets and the second semiconductor layer 12a2 for nano-sheets may be formed on both sides of the second source and drain 24. The first semiconductor layer 12a1 for nano-sheets and the second semiconductor layer 12a2 for nano-sheets may also be referred to as second nano-sheets 12a1 and 12a2.

In addition, through the previous removal process, a first hole 29a and a third hole 29c may be respectively formed in a portion from which the first sacrificial semiconductor layer (11a1 in FIG. 9A) and the third sacrificial semiconductor layer (11a3 in FIG. 9A) are removed. A second hole 29b and a fourth hole 29d may be respectively formed in a portion from which the second sacrificial semiconductor layer (11a2 in FIG. 9A) and the fourth sacrificial semiconductor layer (11a4 in FIG. 9A) are removed. In addition, a third opening 29e may be formed in a portion from which the mask patterns (16 in FIG. 9A) and the dummy gates 14 are removed.

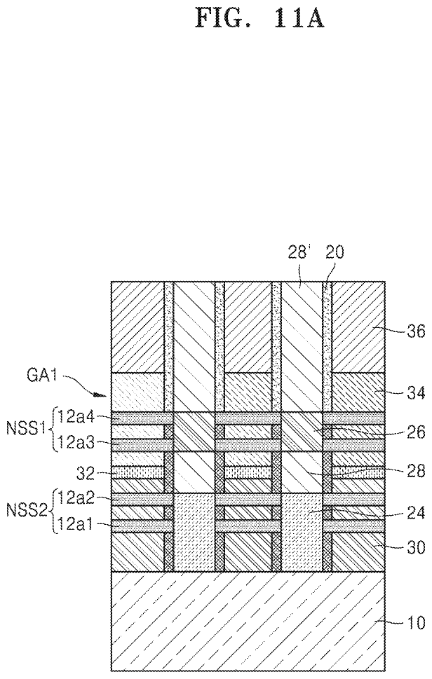

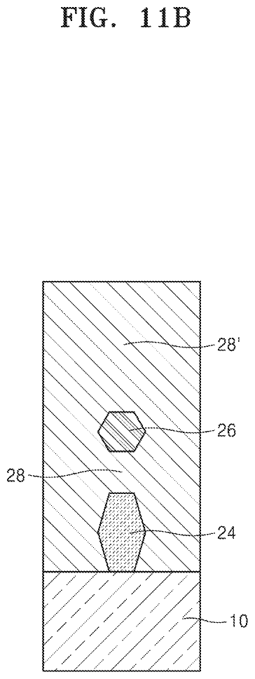

Referring to FIGS. 11A and 11B, a second insulating layer 30 may be buried and formed in portions of the first hole (29a in FIG. 10A), the second hole (29b in FIG. 10A), and the third hole (29c in FIG. 10A). The second insulating layer 30 may include an oxide layer. In addition, a transistor isolation insulating layer 32 may be formed in portions of the third hole 29c.

Subsequently, first gate structures GA1 and 34 may be formed in a portion of the third hole 29c, the fourth hole 29d, and a portion of the third opening 29e. The first gate structures GA1 and 34 may include a first gate insulating layer and a first gate metal layer. A first hard mask 36 may be formed in the third opening 29e of the first gate structures GA1 and 34. The first hard mask 36 may include silicon nitride, polysilicon, an SOH material, or a combination thereof, or other materials.

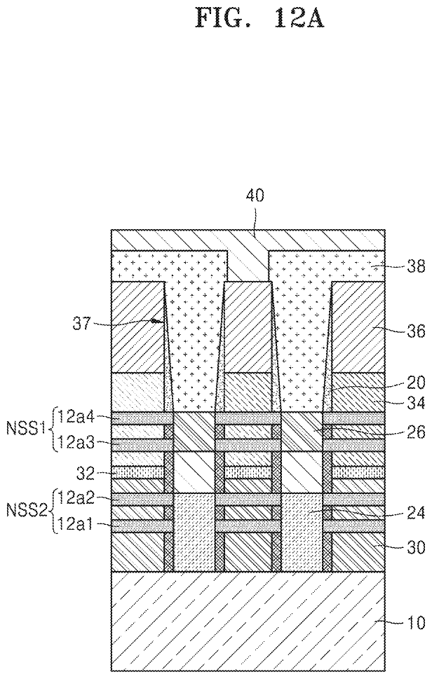

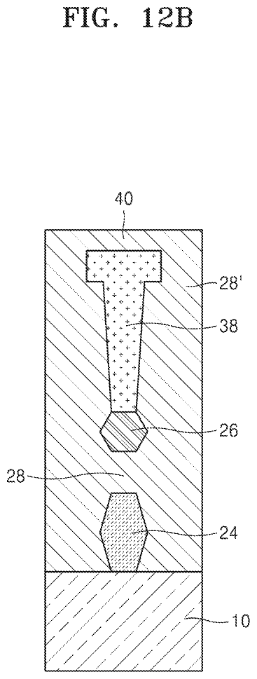

Referring to FIGS. 12A and 12B, a fourth opening 37 for exposing the first source and drain 26 may be formed by etching the first insulating layer (28′ in FIG. 11A) by using the first hard mask 36 as an etching mask. According to the formation of the fourth opening 37, a first outer spacer 20 may be formed in the first insulating layer (28′ in FIG. 11A).

A first metal wiring layer 38 may be formed in the fourth opening 37 and may be electrically connected to the first source and drain 26. The first metal wiring layer 38 may be connected to the first source and drain 26 and may extend in the first horizontal direction (X direction). Subsequently, a first wiring insulating layer 40 may be formed on the first metal wiring layer 49.

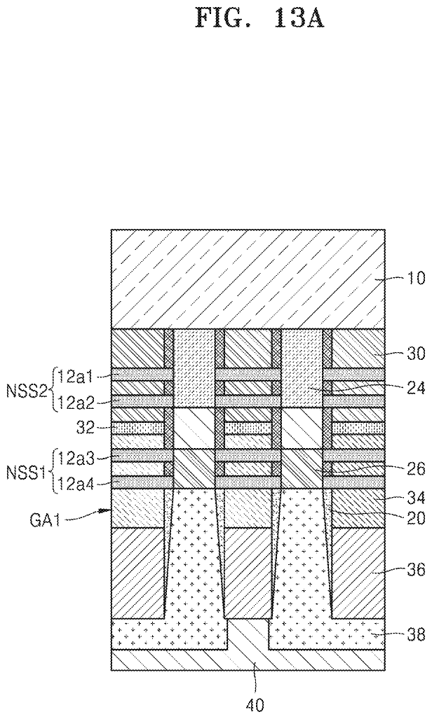

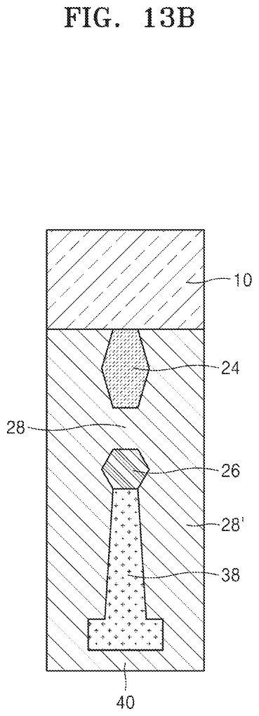

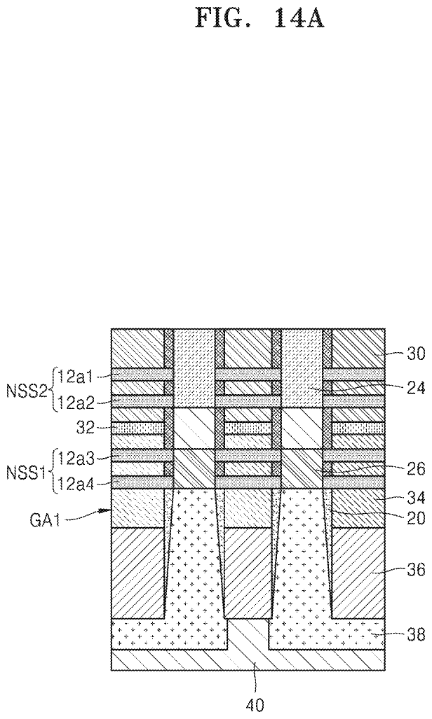

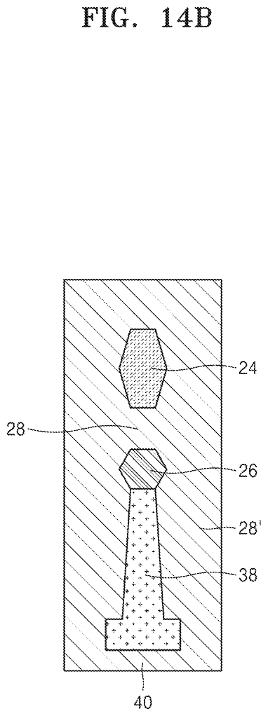

Referring to FIGS. 13A and 13B, 14A, and 14B, the results of FIGS. 12A and 12B are inverted. Accordingly, as shown in FIGS. 13A and 13B, the substrate 10 may be disposed on the upper side of the results. As shown in FIGS. 14A and 14B, the rear surface of the substrate 10 may be polished.

Although it is illustrated in FIGS. 14A and 14B that the rear surface of the substrate 10 is completely removed, the substrate 10 may be used as a mask layer through a patterning process if necessary.

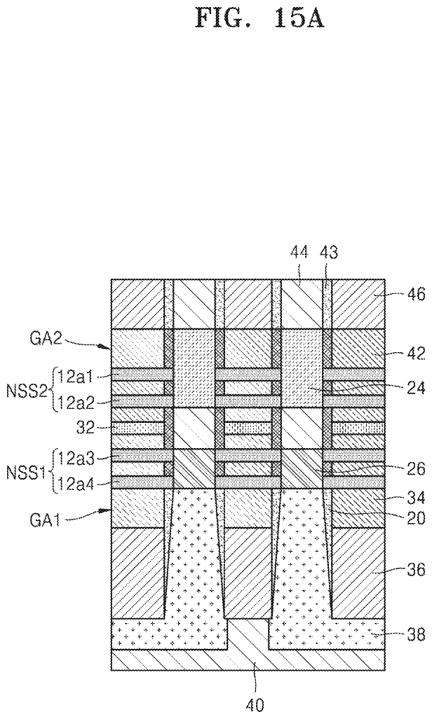

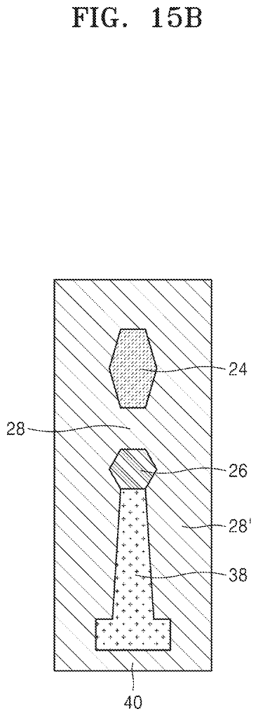

Referring to FIGS. 15A and 15B, third insulating patterns 44 may be formed on the second source and drain 24, as shown in FIG. 15A. A second outer spacer 43 may be formed on both sidewalls of the third insulating patterns 44.

After the second insulating layer (30 in FIG. 14A) is removed by using the third insulating patterns 44 and the second outer spacer 43 as a mask, second gate structures GA2 and 42 may be formed in a portion from which the second insulating layer (30 in FIG. 14A) is removed. The second gate structures GA2 and 42 may include a second gate insulating layer and a second gate metal layer.

The second gate structures GA2 and 42 may be formed in portions of the first hole (29a in FIG. 10A), the second hole (29b in FIG. 10A), and the third hole (29c in FIG. 10A). The second gate structures GA2 and 42 may be formed on the upper portion of the first semiconductor layer 12a1 for nano-sheets, between the first semiconductor layer 12a1 for nano-sheets and the first semiconductor layer 12a1 for nano-sheets, and the lower portion of the second semiconductor layer 12a2 for nano-sheets. Thus, the transistor isolation insulating layer 32 may be a gate isolation insulating layer for separating the first gate structures GA1 and 34 and the second gate structures GA2 and 42 in the vertical direction (Z direction).

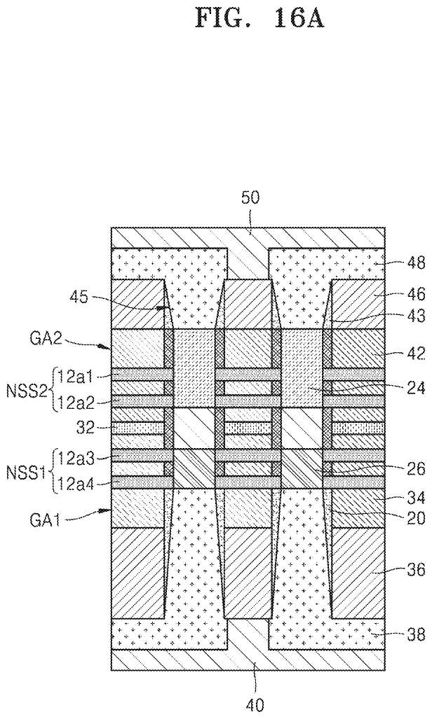

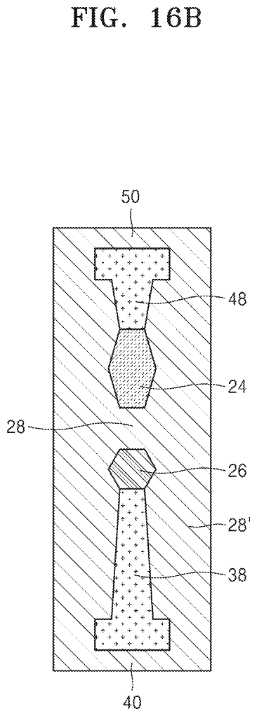

Referring to FIGS. 16A and 16B, a fifth opening 45 exposing the second source and drain 24 may be formed by selectively etching the fourth insulating patterns 44. A second metal wiring layer 48 may be formed in the fifth opening 45. The second metal wiring layer 48 may be electrically connected to the second source and drain 24.

The second metal wiring layer 48 may be connected to the second source and drain 24 and may extend in the first horizontal direction (X direction). Subsequently, a second wiring insulating layer 50 may be formed on the second metal wiring layer 48. Through the above-described manufacturing process, the integrated circuit semiconductor device EX1 may be completed.

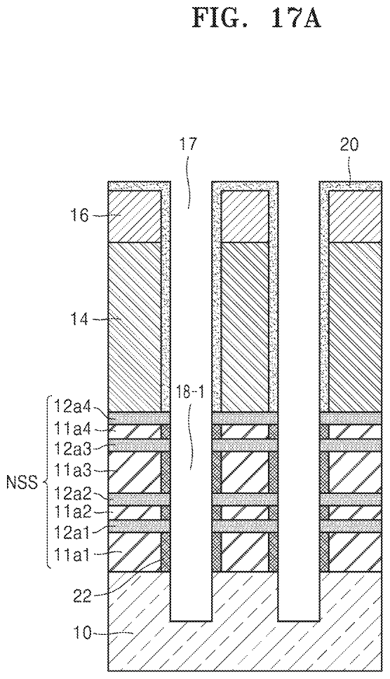

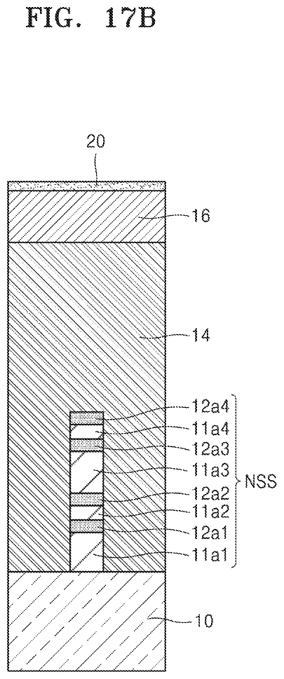

FIGS. 17A through 25B are cross-sectional views for describing a method of manufacturing the integrated circuit semiconductor device of FIGS. 3A and 3B.

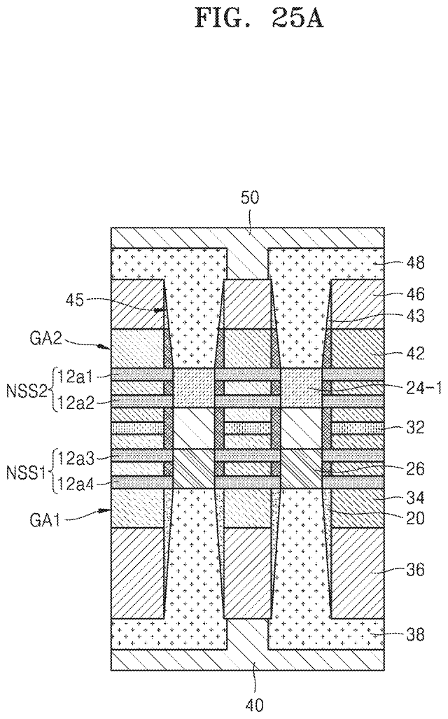

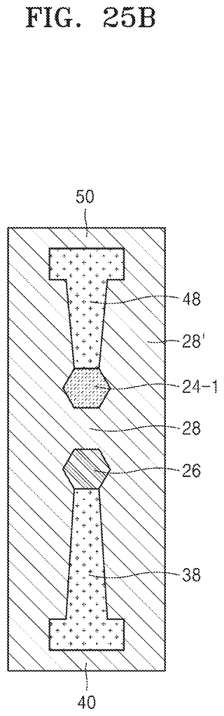

Specifically, FIGS. 17A through 25A illustrate a method of manufacturing the integrated circuit semiconductor device EX2 of FIG. 3A, and cross-sectional views are taken along a line X1-X1′ of FIG. 1. FIGS. 17B through 25B illustrate a method of manufacturing the integrated circuit semiconductor device EX3 of FIG. 3B, and cross-sectional views are taken along a line Y1-Y1′ of FIG. 1. In FIGS. 17A and 25B, descriptions given with reference to FIGS. 3A and 3B are briefly given or omitted. Furthermore, in FIGS. 17A and 25B, descriptions given with reference to FIGS. 6A and 16B are briefly given or omitted. First, the processes of FIGS. 6A, 6B, 7A, and 7B are performed.

Referring to FIGS. 17A and 17B, the nano-sheet stack structure NSS and the substrate 10 may be selectively etched by using the dummy gates 14, the mask patterns 16, and the first outer spacer 20 as an etching mask. Then, a second opening 18-1 may be formed in the nano-sheet stack structure NSS and the substrate 10. The second opening 18-1 may communicate with the first opening (17 in FIG. 7A). The bottom of the second opening 18-1 may be the inside of the substrate 10.

Subsequently, an inner spacer 22 may be selectively formed on both sidewalls of the fourth sacrificial semiconductor layer 11a4, the third sacrificial semiconductor layer 11a3, the second sacrificial semiconductor layer 11a2, and the first sacrificial semiconductor layer 11a1 in the second opening 18-1. The inner spacer 22 may include an insulating layer, for example, an oxide layer.

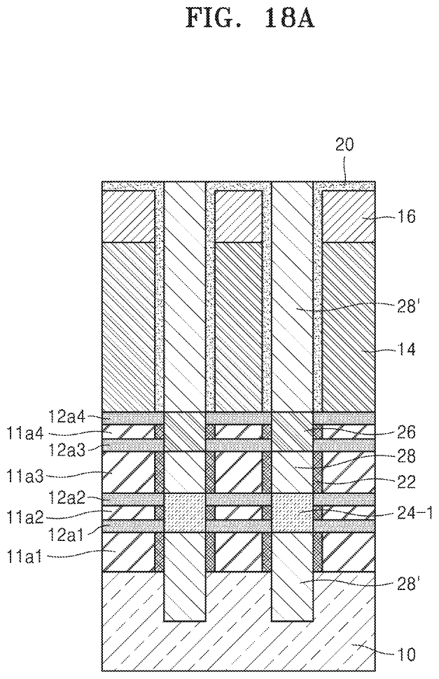

Referring to FIGS. 18A and 18B, a first source and drain 26, a second source and drain 24-1, a transistor isolation insulating layer 28, and a first insulating layer 28′ may be formed in the first opening (17 in FIG. 17A) and the second opening (18-1 in FIG. 17A). The upper surface of the first insulating layer 28′ in the second opening (18-1 in FIG. 17A) may be formed up to the upper surface of the first sacrificial semiconductor layer 11a1. The transistor isolation insulating layer 28 and the first insulating layer 28′ may be simultaneously formed. The transistor isolation insulating layer 28 and the first insulating layer 28′ may include oxide layers.

The first source and drain 26 and the second source and drain 24-1 may be epitaxial layers formed through an epitaxial growth method. The first source and drain 26 may be an epitaxial layer that is epitaxially-grown from both sidewalls of the fourth semiconductor layer 12a4 for nano-sheets and the third semiconductor layer 12a3 for nano-sheets. The second source and drain 24-1 may be an epitaxial layer that is epitaxially-grown from both sidewalls of the first semiconductor layer 12a1 for nano-sheets and the second semiconductor layer 12a2 for nano-sheets.

The first source and drain 26 and the second source and drain 24-1 may be simultaneously formed. The first source and drain 26 and the second source and drain 24-1 may be silicon epitaxial layers. A transistor isolation insulating layer 28 separating the first source and drain 26 and the second source and drain 24-1 in the vertical direction (Z direction) may also be referred to as a source and drain isolation insulating layer.

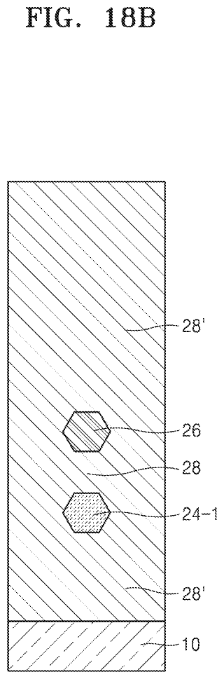

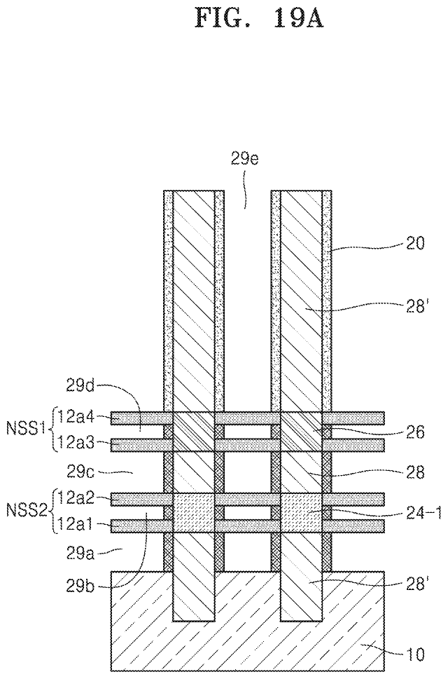

Referring to FIGS. 19A and 19B, the mask patterns (16 in FIG. 18A) and the dummy gates 14 may be removed by using the first insulating layer 28′ and the first outer spacer 20 as a mask. Subsequently, the fourth sacrificial semiconductor layer (11a4 in FIG. 17A), the third sacrificial semiconductor layer (11a3 in FIG. 17A), the second sacrificial semiconductor layer (11a2 in FIG. 17A), and the first sacrificial semiconductor layer (11a1 in FIG. 17A) may be sequentially removed by using the first insulation layer 28′ and the first outer spacer 20 as a mask. In the previous removal process, the first outer spacer 20 formed on the upper surface of the first insulating layer 28′ may be etched.

In this case, a first nano-sheet stack structure NSS1 including the third semiconductor layer 12a3 for nano-sheets and the fourth semiconductor layer 12a4 for nano-sheets may be formed on both sides of the first source and drain 26. The third semiconductor layer 12a3 for nano-sheets and the fourth semiconductor layer 12a4 for nano-sheets may also be referred to as first nano-sheets 12a3 and 12a4.

A second nano-sheet stack structure NSS2 including the first semiconductor layer 12a1 for nano-sheets and the second semiconductor layer 12a2 for nano-sheets may be formed on both sides of the second source and drain 24. The first semiconductor layer 12a1 for nano-sheets and the second semiconductor layer 12a2 for nano-sheets may also be referred to as second nano-sheets 12a1 and 12a2.

In addition, through the previous removal process, a first hole 29a and a third hole 29c may be respectively formed in a portion from which the first sacrificial semiconductor layer (11a1 in FIG. 17A) and the third sacrificial semiconductor layer (11a3 in FIG. 17A) are removed. A second hole 29b and a fourth hole 29d may be respectively formed in a portion from which the second sacrificial semiconductor layer (11a2 in FIG. 17A) and the fourth sacrificial semiconductor layer (11a4 in FIG. 17A) are removed. In addition, a third opening 29e may be formed in a portion from which the mask patterns (16 in FIG. 17A) and the dummy gates 14 are removed.

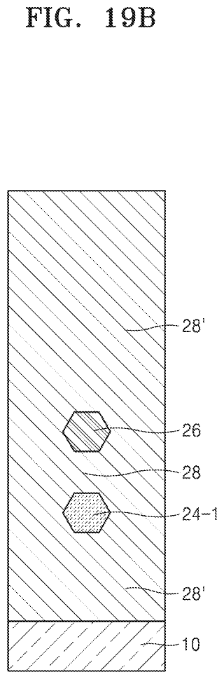

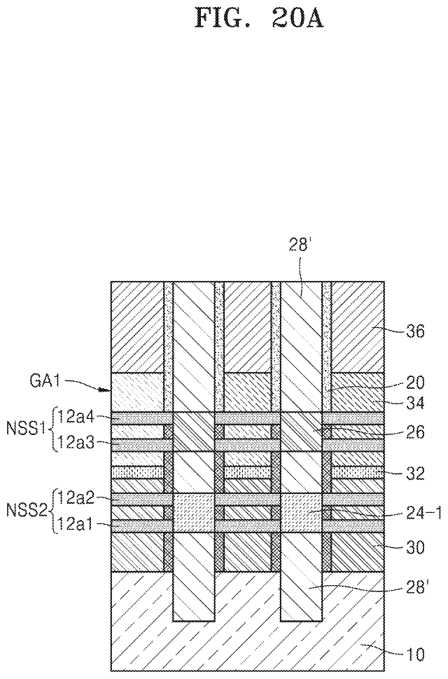

Referring to FIGS. 20A and 20B, a second insulating layer 30 may be buried and formed in portions of the first hole (29a in FIG. 19A), the second hole (29b in FIG. 19A), and the third hole (29c in FIG. 19A). The second insulating layer 30 may include an oxide layer. In addition, a transistor isolation insulating layer 32 may be formed in portions of the third hole 29c.

Subsequently, first gate structures GA1 and 34 may be formed in a portion of the third hole 29c, the fourth hole 29d, and a portion of the third opening 29c. The first gate structures GA1 and 34 may include a first gate insulating layer and a first gate metal layer. A first hard mask 36 may be formed in the third opening 29e of the first gate structures GA1 and 34. The first hard mask 36 may include silicon nitride, polysilicon, an SOH material, or a combination thereof, or other materials.

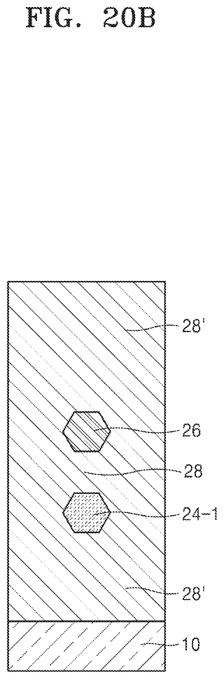

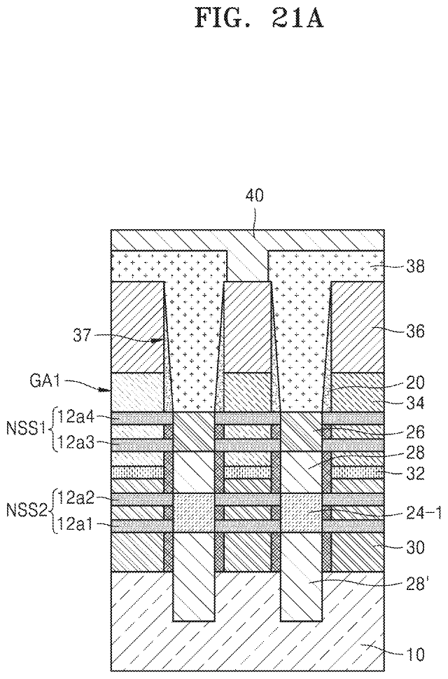

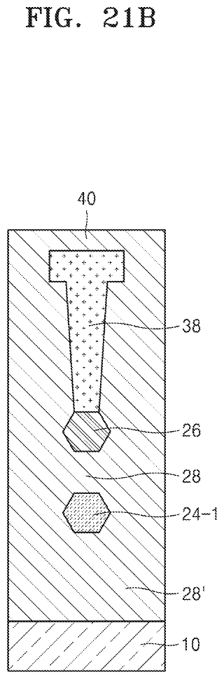

Referring to FIGS. 21A and 21B, a fourth opening 37 exposing the first source and drain 26 may be formed by etching the first insulating layer (28′ in FIG. 20A) by using the first hard mask 36 as an etching mask. According to the formation of the fourth opening 37, a first outer spacer 20 may be formed in the first insulating layer (28′ in FIG. 20A).

A first metal wiring layer 38 may be formed in the fourth opening 37 and may be electrically connected to the first source and drain 26. The first metal wiring layer 38 may be connected to the first source and drain 26 and may extend in the first horizontal direction (X direction). Subsequently, a first wiring insulating layer 40 may be formed on the first metal wiring layer 49.

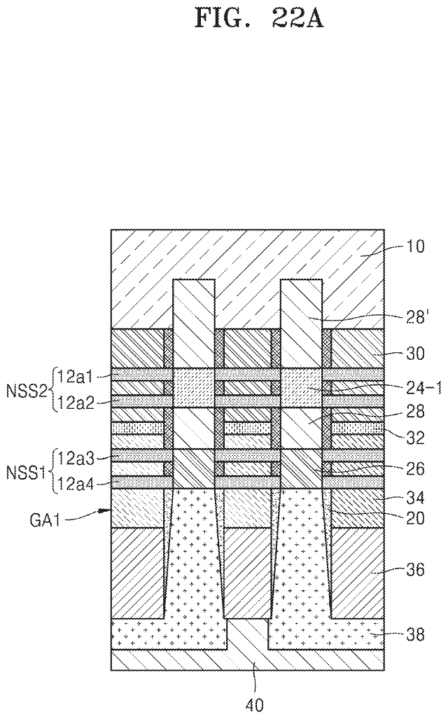

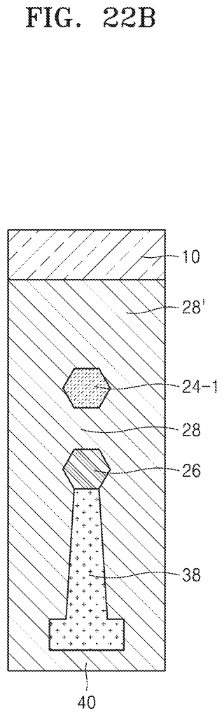

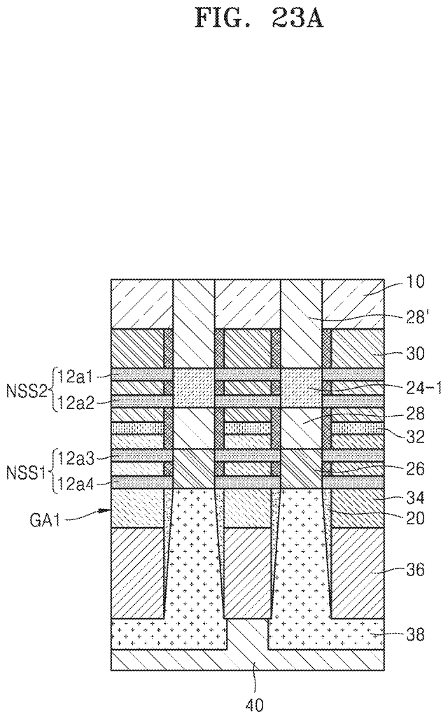

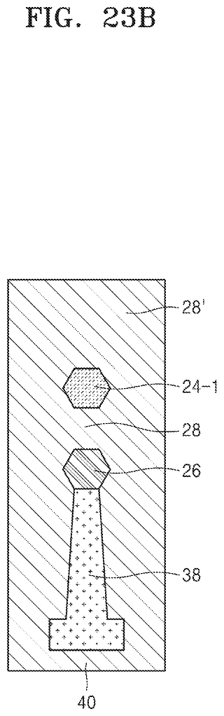

Referring to FIGS. 22A and 23B, the results of FIGS. 21A and 21B are inverted. Accordingly, as shown in FIGS. 22A and 22B, the substrate 10 may be disposed on the upper side. Subsequently, as shown in FIGS. 23A and 23B, the rear surface of the substrate 10 may be polished. The surface of the first insulating layer 28′ may be exposed according to the polishing of the rear surface of the substrate 10.

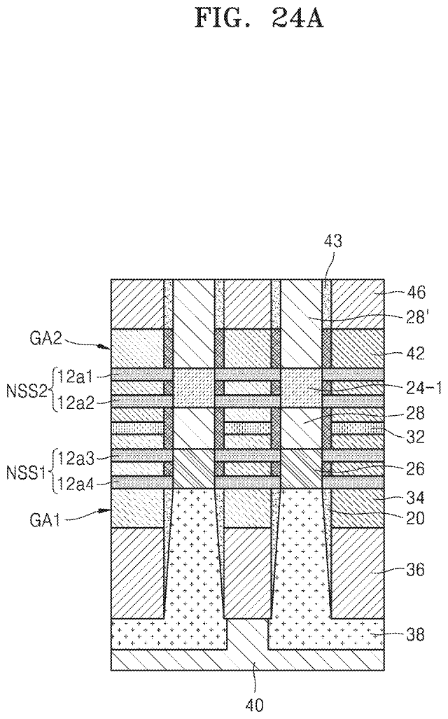

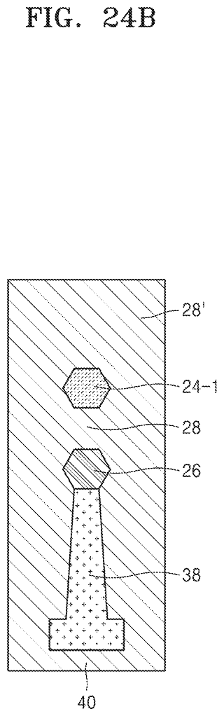

Referring to FIGS. 24A and 24B, after removing the substrate 10 left in the previous process, a second outer spacer 43 may be formed on both sidewalls of the first insulating layer 28′. After the second insulating layer (30 in FIG. 23A) is removed by using the first insulating layer 28′ and the second outer spacer 43 as a mask, second gate structures GA2 and 42 may be formed in a portion from which the second insulating layer (30 in FIG. 14A) is removed. The second gate structures GA2 and 42 may include a second gate insulating layer and a second gate metal layer.

The second gate structures GA2 and 42 may be formed in portions of the first hole (29a in FIG. 10A), the second hole (29b in FIG. 19A), and the third hole (29c in FIG. 19A). The second gate structures GA2 and 42 may be formed on the upper portion of the first semiconductor layer 12a1 for nano-sheets, between the first semiconductor layer 12a1 for nano-sheets and the first semiconductor layer 12a1 for nano-sheets, and the lower portion of the second semiconductor layer 12a2 for nano-sheets.

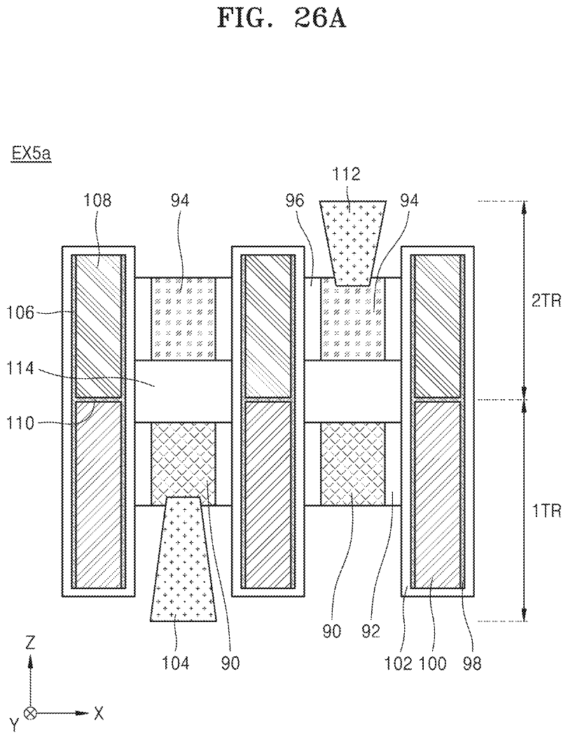

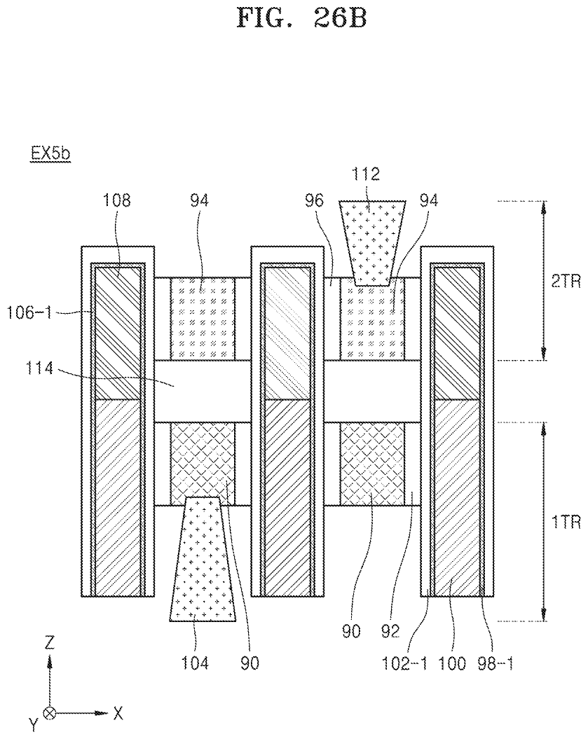

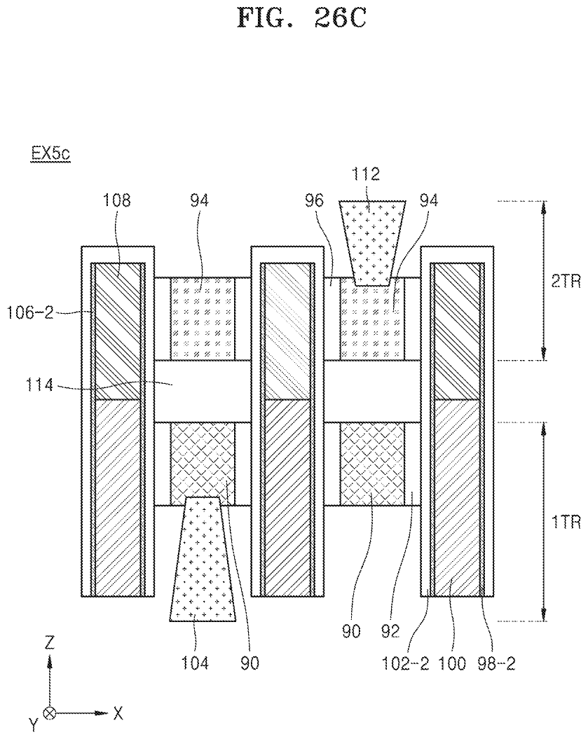

Referring to FIGS. 25A and 26B, a fifth opening 45 exposing the second source and drain 24 may be formed by selectively etching the first insulating layer 28′. A second metal wiring layer 48 may be formed in the fourth opening 45. The second metal wiring layer 48 may be electrically connected to the second source and drain 24.

The second metal wiring layer 48 may be connected to the second source and drain 24 and may extend in the first horizontal direction (X direction). Subsequently, a second wiring insulating layer 50 may be formed on the second metal wiring layer 48. Through the above-described manufacturing process, the integrated circuit semiconductor device EX2 may be completed.

FIGS. 26A through 26C are cross-sectional views for describing an integrated circuit semiconductor device according to an example embodiment.

Specifically, in FIGS. 26A through 26C, the same or similar contents as described above are briefly given or omitted.

Referring to FIG. 26A, an integrated circuit semiconductor device EX5a may include a first transistor 1TR and a second transistor 2TR, which are separated from each other by a source and drain isolation insulating layer 114 in the vertical direction (Z direction).

The first transistor 1TR may include a first gate and nano-structure 100, a first source and drain 90, a first inner spacer 92, an outer spacer 102, and a first metal wiring layer 104. The first gate and nano-structure 100 may include a first gate structure and a first nano-sheet structure. In FIG. 26A, the first gate and nano-structure 100 may include a first gate insulating layer 98. The first gate insulating layer 98 may not be disposed on the lower surface of the first gate and nano-structure 100.

The second transistor 2TR may include a second gate and nano-structure 108, a second source and drain 94, a second inner spacer 96, an outer spacer 102, and a second metal wiring layer 112. The second gate and nano-structure 108 may include a second gate structure and a second nano-sheet structure. In FIG. 26A, the second gate and nano-structure 108 may include a second gate insulating layer 106. The second gate insulating layer 106 may not be disposed on an upper surface of the second gate and nano-structure 108.

An integrated circuit semiconductor device EX5a may include a connection gate insulating layer 110 connecting the first gate insulating layer 98 to the second gate insulating layer 106 in a first horizontal direction (X direction) at a level of the source and drain isolation insulating layer 114. Thus, the first gate and nano-structure 100 and the second gate and nano-structure 108 may be divided by the connection gate insulating layer 110 at the level of the source and drain isolation insulating layer 114. The integrated circuit semiconductor device EX5a may include an outer spacer 102 surrounding the first gate and nano-structure 100 and the second gate and nano-structure 108.

Referring to FIG. 26B, an integrated circuit semiconductor device EX5b may be substantially the same as the integrated circuit semiconductor device EX5a of FIG. 26A except for the connection relationship between the first gate insulating layer 98-1 and the second gate insulating layer 106-1 and the formation position of the outer spacer 102-1 when compared to the integrated circuit semiconductor device EX5a of FIG. 26A.

The first transistor 1TR may include a first gate insulating layer 98-1, and the second transistor 2TR may include a second gate insulating layer 106-1. In some embodiments, the first gate insulating layer 98-1 and the second gate insulating layer 106-1 may be directly connected to each other.

In some embodiments, the first gate insulating layer 98-1 may not be disposed on the lower surface of the first gate and nano-structure 100, and the second gate insulating layer 106-1 may be disposed on the upper surface of the second gate and nano-structure 108. In some embodiments, the outer spacer 102-1 may be disposed to surround the first gate and nano-structure 100 and the second gate and nano-structure 108 except for the lower surface of the first gate and nano-structure 100.

Referring to FIG. 26C, an integrated circuit semiconductor device EX5c may be substantially the same as the integrated circuit semiconductor device EX5b of FIG. 26B except for the formation position of the first gate insulating layer 98-2 and the second gate insulating layer 106-2 and the formation position of the outer spacer 102-2 when compared to the integrated circuit semiconductor device EX5b of FIG. 26B.

In the integrated circuit semiconductor device EX5c, the first gate insulating layer 98-1 may not be disposed on the lower surface of the first gate and nano-structure 100, and the second gate insulating layer 106-2 may not be disposed on the upper surface of the second gate and nano-structure 108. The outer spacer 102-2 may be disposed to surround the first gate and nano-structure 100 and the second gate and nano-structure 108 except for the lower surface of the first gate and nano-structure 100.

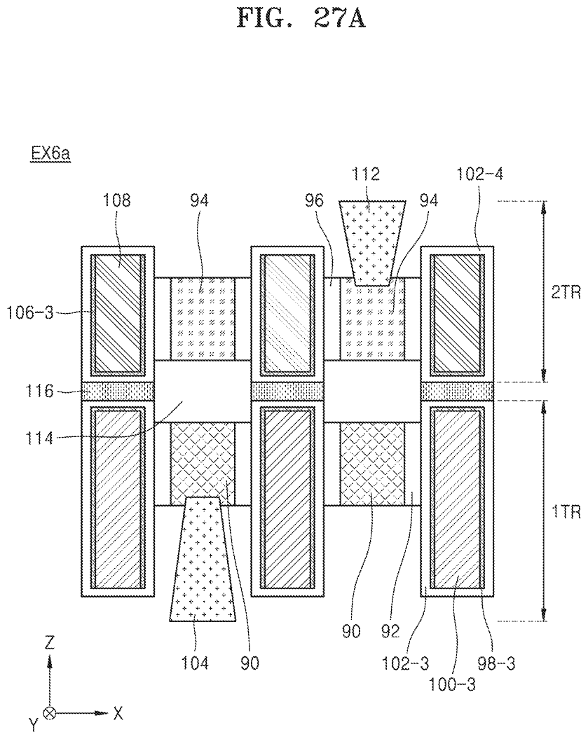

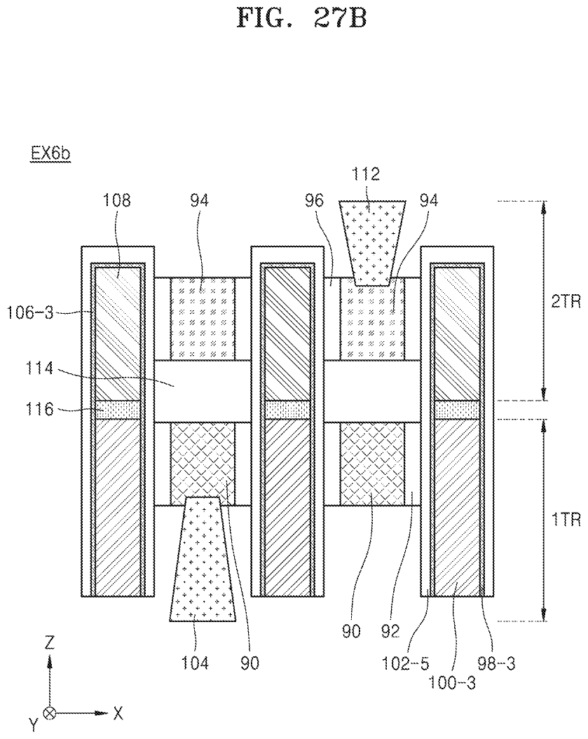

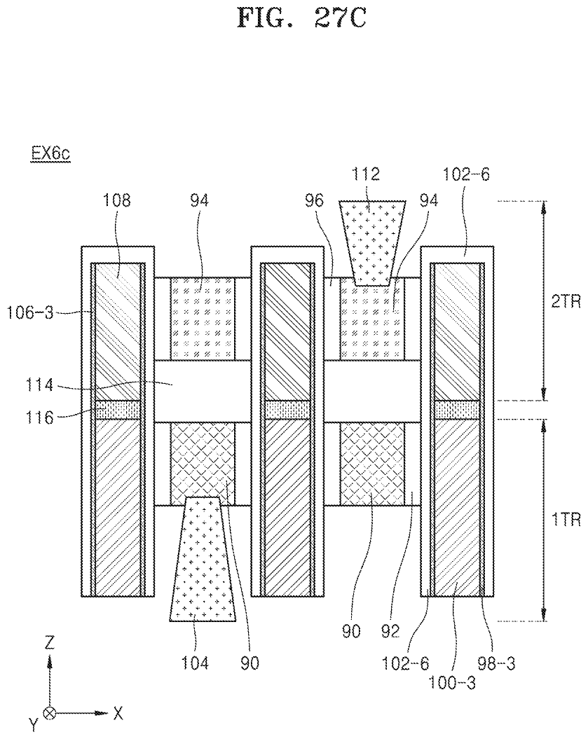

FIGS. 27A through 27C are cross-sectional views for describing an integrated circuit semiconductor device according to an example embodiment.

Specifically, in FIGS. 27A through 27C, the same or similar contents as described above are briefly given or omitted.

Referring to FIG. 27A, an integrated circuit semiconductor device EX6a may include a first transistor 1TR and a second transistor 2TR, which are separated from each other by a source and drain isolation insulating layer 114 in the vertical direction (Z direction).

The first transistor 1TR may include a first gate and nano-structure 100-3, a first source and drain 90, a first inner spacer 92, an outer spacer 102-3, and a first metal wiring layer 104. The first gate and nano-structure 100-3 may include a first gate structure and a first nano-sheet structure. In FIG. 27A, the first gate and nano-structure 100-3 may include a first gate insulating layer 98-3. The first gate insulating layer 98-3 may not be disposed on the lower surface of the first gate and nano-structure 100.

The second transistor 2TR may include a second gate and nano-structure 108, a second source and drain 94, a second inner spacer 96, an second outer spacer 102-4, and a second metal wiring layer 112. The second gate and nano-structure 108 may include a second gate structure and a second nano-sheet structure. In FIG. 27A, the second gate and nano-structure 108 may include a second gate insulating layer 106-3. The second gate insulating layer 106-3 may not be disposed on an upper surface of the second gate and nano-structure 108.

The integrated circuit semiconductor element Ex6a may include a gate isolation insulating layer 116 separating the first gate and nano-structure 100-3 and the second gate and nano-structure 108 in a vertical direction (Z direction). Thus, the first gate and nano-structure 100 and the second gate and nano-structure 108 may be divided by the gate isolation insulating layer 116. The integrated circuit semiconductor device EX6a may include a first outer spacer 102-3 surrounding the first gate and nano-structure 100, and a second outer spacer 102-4 surrounding the second gate and nano-structure 108. The first outer spacer 102-3 and the second outer spacer 102-4 may be separated from each other by the gate isolation insulating layer 116.

Referring to FIG. 27B, an integrated circuit semiconductor device EX6b may be substantially the same as the integrated circuit semiconductor device EX5a of FIG. 26A except for the connection relationship between the first gate insulating layer 98-3 and the second gate insulating layer 106-3 and the formation position of the outer spacer 102-5 when compared to the integrated circuit semiconductor device EX6a of FIG. 27A.

The first transistor 1TR may include a first gate insulating layer 98-3, and the second transistor 2TR may include a second gate insulating layer 106-3. The first gate insulating layer 98-3 and the second gate insulating layer 106-3 may be directly connected to each other.

The first gate insulating layer 98-3 may not be disposed on the lower surface of the first gate and nano-structure 100-3, and the second gate insulating layer 106-3 may be disposed on the upper surface of the second gate and nano-structure 108. The outer spacer 102-5 may be disposed to surround the first gate and nano-structure 100-3 and the second gate and nano-structure 108 except for the lower surface of the first gate and nano-structure 100.

Referring to FIG. 27C, an integrated circuit semiconductor device EX6c may be substantially the same as the integrated circuit semiconductor device EX6b of FIG. 27B except for the position of the first gate insulating layer 98-3 and the second gate insulating layer 106-3 and the position of the outer spacer 102-6 when compared to the integrated circuit semiconductor device EX6b of FIG. 27B.

In the integrated circuit semiconductor device EX6c, the first gate insulating layer 98-3 may not be disposed on the lower surface of the first gate and nano-structure 100-3, and the second gate insulating layer 106-3 may not be disposed on the upper surface of the second gate and nano-structure 108. The outer spacer 102-6 may be disposed to surround the first gate and nano-structure 100-3 and the second gate and nano-structure 108 except for the lower surface of the first gate and nano-structure 100-3.

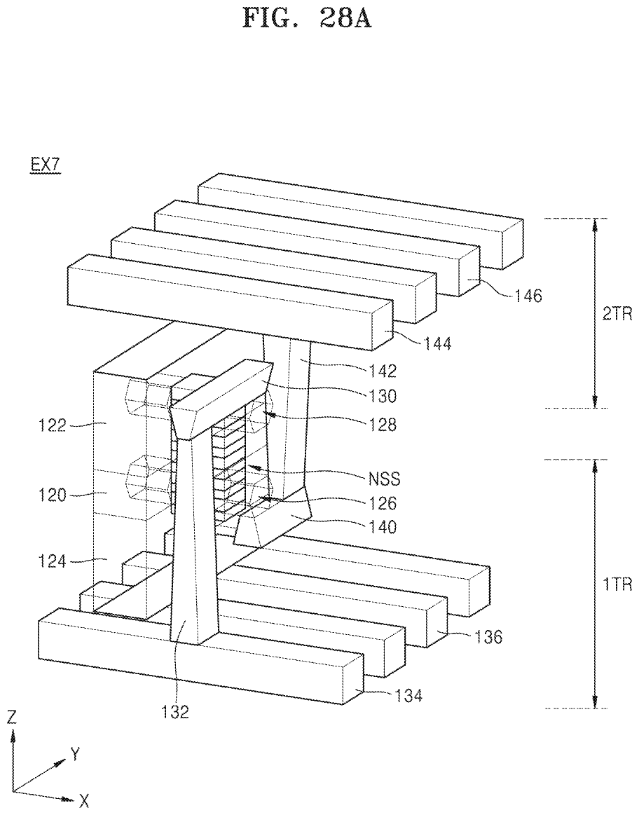

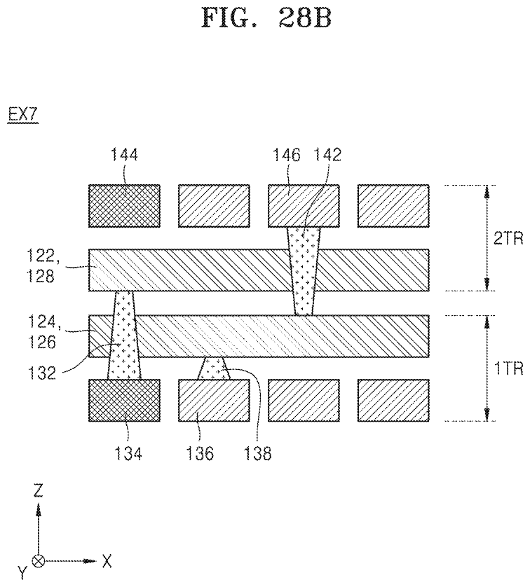

FIGS. 28A and 28B are views for describing an integrated circuit semiconductor device according to an example embodiment.

Specifically, in FIGS. 28A through 28C, the same or similar contents as described above are briefly given or omitted. FIG. 28A is a perspective view of an integrated circuit semiconductor device EX7, and FIG. 28B is a cross-sectional view of the integrated circuit semiconductor device EX7.

An integrated circuit semiconductor device EX7 may include a first transistor 1TR and a second transistor 2TR, which are separated from each other by a transistor isolation insulating layer 120 in the vertical direction (Z direction). The first transistor 1TR and the second transistor 2TR may include a nano-sheet stack structure NSS.

The first transistor 1TR may include a first gate structure 124 and a first source and drain 126. The second transistor 2TR may include a second gate structure 122 and a second source and drain 128.

First metal wiring layers 130, 132, 134, and 136 may be connected to the second source and drain 128 of the second transistor 2TR and the first gate structure 124 of the first transistor 1TR. The first metal wiring layers 130, 132, 134, and 136 may include plug and wiring metal layers 130 and 132 arranged on the second source and drain 128 in a vertical direction (Z direction) and a second horizontal direction (Y direction), and wiring metal layers 134 and 136 arranged in a first horizontal direction (X direction) with respect to the first gate structure 124.

The wiring metal layer 136 may be connected to the first gate structure 124 via the plug metal layer 138 arranged in the vertical direction (Z direction), as shown in FIG. 28B. The wiring metal layer 134 may be a power line for transmitting power via the plug and the wiring metal layers 130 and 132. The wiring metal layer 136 may be a signal line for transmitting signals.

Second metal wiring layers 140, 142, 144, and 146 may be connected to the first source and drain 126 and the second gate structure 122 of the second transistor 2TR. The second metal wiring layers 140, 142, 144, and 146 may include plug and wiring metal layers 140 and 142 arranged on the first source and drain 126 in a vertical direction (Z direction) and the second horizontal direction (Y direction), and wiring metal layers 144 and 146 arranged in a first horizontal direction (X direction) with respect to the second gate structure 122. The wiring metal layer 146 may be a power line for transmitting power via the plug and the wiring metal layers 140 and 142. The wiring metal layer 144 may be a signal line for transmitting signals.

While the inventive concept has been particularly shown and described with reference to embodiments thereof, it will be understood that various changes in form and details may be made therein without departing from the spirit and scope of the following claims.

What is claimed is:

1. An integrated circuit semiconductor device comprising:
a first transistor comprising a first nano-sheet stack structure, a first gate structure, and a first source and drain, the first transistor having a first horizontal direction, a second horizontal direction perpendicular to the first horizontal direction, and a vertical direction perpendicular to the first horizontal direction and the second horizontal direction; and
a second transistor comprising a second nano-sheet stack structure, a second gate structure, and a second source and drain, the second transistor being separated from the first transistor by a transistor isolation insulating layer in the vertical direction,
wherein the first nano-sheet stack structure comprises a plurality of first nano-sheet stacks spaced apart from each other in the first horizontal direction, wherein each of the plurality of first nano-sheet stacks comprises a plurality of first nano-sheets stacked in the vertical direction,
wherein the first gate structure extends in the second horizontal direction and surrounds the first nano-sheet stack structure in the vertical direction,
wherein the first source and drain is disposed on both sides of at least one first nano-sheet stack in the first horizontal direction,
wherein the second nano-sheet stack structure comprises a plurality of second nano-sheet stacks spaced apart from each other in the first horizontal direction, wherein each of the plurality of second nano-sheet stacks comprises a plurality of second nano-sheets stacked in the vertical direction, and
wherein the second gate structure extends in the second horizontal direction and surrounds the second nano-sheet stack structure in the vertical direction,
wherein the second source and drain is disposed on both sides of at least one second nano-sheet stack in the first horizontal direction.

2. The integrated circuit semiconductor device of claim 1, wherein the first transistor and the second transistor comprise different types of transistors.

3. The integrated circuit semiconductor device of claim 1, wherein a channel length of the first transistor is different from a channel length of the second transistor.

4. The integrated circuit semiconductor device of claim 1, wherein the transistor isolation insulating layer comprises a gate isolation insulating layer separating the first gate structure and the second gate structure from each other in the vertical direction.

5. The integrated circuit semiconductor device of claim 1, wherein the transistor isolation insulating layer comprises a source and drain isolation insulating layer separating the first source and drain and the second source and drain from each other in the vertical direction.

6. The integrated circuit semiconductor device of claim 1, further comprising:
a first metal wiring layer connected in an inverse vertical direction to the first source and drain; and
a second metal wiring layer connected in the vertical direction to the second source and drain.

7. The integrated circuit semiconductor device of claim 1, wherein the first source and drain and the second source and drain comprise epitaxial layers doped with impurities.

8. The integrated circuit semiconductor device of claim 1, wherein the first source and drain, and the second source and drain comprise epitaxial layers having a higher impurity concentration inside than outside in the first horizontal direction.

9. The integrated circuit semiconductor device of claim 1, wherein the first source and drain, and the second source and drain comprise epitaxial layers having a lower impurity concentration inside than outside in the second horizontal direction.

10. The integrated circuit semiconductor device of claim 1, further comprising:
a first hard mask disposed under the first gate structure in an inverse vertical direction of the first transistor; and
a second hard mask disposed on the second gate structure in the vertical direction of the first transistor.

11. The integrated circuit semiconductor device of claim 1, wherein the first gate structure comprises a first gate insulating layer and a first gate metal layer, the second gate structure comprises a second gate insulating layer and a second gate metal layer, and a width of the first gate structure is greater than a width of the first gate structure in the first horizontal direction.

12. An integrated circuit semiconductor device comprising:
a first transistor comprising a first nano-sheet stack structure, a first gate structure, and a first source and drain, the first transistor having a first horizontal direction, a second horizontal direction perpendicular to the first horizontal direction, and a vertical direction perpendicular to the first horizontal direction and the second horizontal direction; and
a second transistor comprising a second nano-sheet stack structure, a second gate structure, and a second source and drain, the second transistor being separated from the first transistor by a transistor isolation insulating layer in the vertical direction,
wherein the first nano-sheet stack structure comprises a plurality of first nano-sheet stacks spaced apart from each other in the first horizontal direction, wherein each of the plurality of first nano-sheet stacks comprises a plurality of first nano-sheets stacked in the vertical direction,
wherein the first gate structure extends in the second horizontal direction and surrounds the first nano-sheet stack structure in the vertical direction,
wherein the first source and drain is disposed on both sides of at least one first nano-sheet stack structure in the first horizontal direction,
wherein the second nano-sheet stack structure comprises a plurality of second nano-sheet stacks spaced apart from each other in the first horizontal direction, wherein each of the plurality of second nano-sheet stacks comprises a plurality of second nano-sheets stacked in the vertical direction,
wherein the second gate structure extends in the second horizontal direction and surrounds the second nano-sheet stack structure in the vertical direction,
wherein the second source and drain is disposed on both sides of at least one second nano-sheet stack in the first horizontal direction,
wherein the transistor isolation insulating layer comprises a gate isolation insulating layer separating the first gate structure and the second gate structure in the vertical direction, and a source and drain isolation insulating layer separating the first source and drain and the second source and drain in the vertical direction; and
wherein a height of the second source and drain is greater than or equal to a height of the first source and drain.

13. The integrated circuit semiconductor device of claim 12, further comprising:
a first metal wiring layer connected in an inverse vertical direction to the first source and drain; and
a second metal wiring layer connected in the vertical direction to the second source and drain.

14. The integrated circuit semiconductor device of claim 12, wherein the first source and drain, and the second source and drain comprise epitaxial layers doped with impurities.

15. The integrated circuit semiconductor device of claim 12, further comprising:
a first hard mask disposed under the first gate structure in an inverse vertical direction of the first transistor; and
a second hard mask disposed on the second gate structure in the vertical direction of the first transistor.

16. An integrated circuit semiconductor device comprising:
a transistor isolation insulating layer having a first horizontal direction, a second horizontal direction perpendicular to the first horizontal direction, and a vertical direction perpendicular to the first horizontal direction and the second horizontal direction;
a first transistor arranged under the transistor isolation insulating layer in an inverse vertical direction, the first transistor comprising a first nano-sheet stack structure, a first gate structure, a first source and drain, and a first metal wiring layer; and
a second transistor arranged under the transistor isolation insulating layer in the vertical direction, the second transistor comprising a second nano-sheet stack structure, a second gate structure, a second source and drain, and a second metal wiring layer,
wherein the first nano-sheet stack structure comprises a plurality of first nano-sheet stacks spaced apart from each other in the first horizontal direction, wherein each of the plurality of first nano-sheet stacks comprises a plurality of first nano-sheets stacked in the vertical direction,
wherein the first gate structure extends in the second horizontal direction and surrounds the first nano-sheet stack structure in the vertical direction,
wherein the first source and drain is disposed on both sides of at least one first nano-sheet stack in the first horizontal direction,
wherein the first metal wiring layer is connected to the first source and drain in the inverse vertical direction,
wherein the second nano-sheet stack structure comprises a plurality of second nano-sheet stacks spaced apart from each other in the first horizontal direction, wherein each of the plurality of second nano-sheet stacks comprises a plurality of second nano-sheets stacked in the vertical direction,
wherein the second gate structure extends in the second horizontal direction and surrounds the second nano-sheet stack structure in the vertical direction,
wherein the second source and drain is disposed on both sides of at least one second nano-sheet stack in the first horizontal direction, and
wherein the second metal wiring layer is connected to the second source and drain in the vertical direction.

17. The integrated circuit semiconductor device of claim 16, further comprising:
a first hard mask disposed under the first gate structure in the inverse vertical direction of the transistor isolation insulating layer; and
a second hard mask disposed on the second gate structure in the vertical direction of the transistor isolation insulating layer.

18. The integrated circuit semiconductor device of claim 16, wherein each of the first metal wiring layer and the second metal wiring layer comprise a power line or a signal line.

19. The integrated circuit semiconductor device of claim 16, wherein the first gate structure comprises a first gate insulating layer and a first gate metal layer, and the second gate structure comprises a second gate insulating layer and a second gate metal layer, and the first gate insulating layer and the second gate insulating layer are separated from each other in the vertical direction.

20. The integrated circuit semiconductor device of claim 16, wherein the first gate structure comprises a first gate insulating layer and a first gate metal layer, and the second gate structure comprises a second gate insulating layer and a second gate metal layer, and the first gate insulating layer and the second gate insulating layer are connected to each other in the vertical direction.
